(19) United States
(12) Patent Application Publication
(10) Pub. No.: US 2025/0071612 A1
(43) Pub. Date: Feb. 27, 2025

(54) BIT COMPRESSION OF UPLINK FRONTHAUL DATA

(71) Applicant: Samsung Electronics Co., Ltd., Suwon-si (KR)

(72) Inventors: Shouvik Ganguly, Frisco, TX (US); Aniruddh Venkatakrishnan, Austin, TX (US); Young Han Nam, Plano, TX (US); Mustafa Furkan Ozkoc, The Colony, TX (US)

(21) Appl. No.: 18/789,579

(22) Filed: Jul. 30, 2024

Related U.S. Application Data
(60) Provisional application No. 63/533,544, filed on Aug. 18, 2023.

(51) Int. Cl. H04W 28/06; H04L 5/00; H04W 28/18

(52) U.S. Cl. CPC H04W 28/06; H04L 5/0048; H04W 28/18

(57) ABSTRACT

Methods and apparatuses for a bit compression of uplink fronthaul data in wireless communication systems are provided. The methods of UE comprise: identifying uplink fronthaul data to reduce a data load on an uplink fronthaul link, wherein the uplink fronthaul link is between the RU and a DU; processing the uplink fronthaul data to obtain a set of representative values for a compression operation; selecting, based on the set of representative values, at least one encoding parameter for the compression operation; and transmitting, to the DU, the uplink fronthaul data that is compressed based on the compression operation.

### CROSS-REFERENCE TO RELATED APPLICATIONS AND CLAIM OF PRIORITY

The present application claims priority to U.S. Provisional Patent Application No. 63/533,544, filed on Aug. 18, 2023. The contents of the above-identified patent documents are incorporated herein by reference.

### TECHNICAL FIELD

The present disclosure relates generally to wireless communication systems and, more specifically, the present disclosure relates to a bit compression of uplink fronthaul data in wireless communication systems.

### BACKGROUND

5th generation (5G) or new radio (NR) mobile communications is recently gathering increased momentum with all the worldwide technical activities on the various candidate technologies from industry and academia. The candidate enablers for the 5G/NR mobile communications include massive antenna technologies, from legacy cellular frequency bands up to high frequencies, to provide beamforming gain and support increased capacity, new waveform (e.g., a new radio access technology (RAT)) to flexibly accommodate various services/applications with different requirements, new multiple access schemes to support massive connections, and so on.

### SUMMARY

The present disclosure relates to wireless communication systems and, more specifically, the present disclosure relates to a bit compression of uplink fronthaul data in wireless communication systems.

In one embodiment, a radio unit (RU) in a wireless communication system is provided. The RU comprise a processor configured to: identify uplink fronthaul data to reduce a data load on an uplink fronthaul link, wherein the uplink fronthaul link is between the RU and a distributed unit (DU), process the uplink fronthaul data to obtain a set of representative values for a compression operation, and select, based on the set of representative values, at least one encoding parameter for the compression operation. The RU further comprises a transceiver operably coupled to the processor, the transceiver configured to transmit, to the DU, the uplink fronthaul data that is compressed based on the compression operation.

In another embodiment, a method of an RU is provided. The method comprises: identifying uplink fronthaul data to reduce a data load on an uplink fronthaul link, wherein the uplink fronthaul link is between the RU and a DU; processing the uplink fronthaul data to obtain a set of representative values for a compression operation; selecting, based on the set of representative values, at least one encoding parameter for the compression operation; and transmitting, to the DU, the uplink fronthaul data that is compressed based on the compression operation.

In yet another embodiment, a non-transitory computer-readable medium comprising program code is provided. The non-transitory computer-readable medium, that when executed by at least one processor, causes an electronic device to: identify uplink fronthaul data to reduce a data load on an uplink fronthaul link, wherein the uplink fronthaul link is between the RU and a DU; process the uplink fronthaul data to obtain a set of representative values for a compression operation; select, based on the set of representative values, at least one encoding parameter for the compression operation; and transmit, to the DU, the uplink fronthaul data that is compressed based on the compression operation.

Other technical features may be readily apparent to one skilled in the art from the following figures, descriptions, and claims.

Before undertaking the DETAILED DESCRIPTION below, it may be advantageous to set forth definitions of certain words and phrases used throughout this patent document. The term “couple” and its derivatives refer to any direct or indirect communication between two or more elements, whether or not those elements are in physical contact with one another. The terms “transmit,” “receive,” and “communicate,” as well as derivatives thereof, encompass both direct and indirect communication. The terms “include” and “comprise,” as well as derivatives thereof, mean inclusion without limitation. The term “or” is inclusive, meaning and/or. The phrase “associated with,” as well as derivatives thereof, means to include, be included within, interconnect with, contain, be contained within, connect to or with, couple to or with, be communicable with, cooperate with, interleave, juxtapose, be proximate to, be bound to or with, have, have a property of, have a relationship to or with, or the like. The term “controller” means any device, system, or part thereof that controls at least one operation. Such a controller may be implemented in hardware or a combination of hardware and software and/or firmware. The functionality associated with any particular controller may be centralized or distributed, whether locally or remotely. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

Moreover, various functions described below can be implemented or supported by one or more computer programs, each of which is formed from computer readable program code and embodied in a computer readable medium. The terms “application” and “program” refer to one or more computer programs, software components, sets of instructions, procedures, functions, objects, classes, instances, related data, or a portion thereof adapted for implementation in a suitable computer readable program code. The phrase “computer readable program code” includes any type of computer code, including source code, object code, and executable code. The phrase “computer readable medium” includes any type of medium capable of being accessed by a computer, such as read only memory (ROM), random access memory (RAM), a hard disk drive, a compact disc (CD), a digital video disc (DVD), or any other type of memory. A “non-transitory” computer readable medium excludes wired, wireless, optical, or other communication links that transport transitory electrical or other signals. A non-transitory computer readable medium includes media where data can be permanently stored and media where data can be stored and later overwritten, such as a rewritable optical disc or an erasable memory device.

Definitions for other certain words and phrases are provided throughout this patent document. Those of ordinary skill in the art should understand that in many if not most instances, such definitions apply to prior as well as future uses of such defined words and phrases.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 illustrates an example of wireless network according to various embodiments of the present disclosure;

FIG. 2 illustrates an example of gNB according to various embodiments of the present disclosure;

FIG. 3 illustrates an example of UE according to various embodiments of the present disclosure;

FIGS. 4 and 5 illustrate example of wireless transmit and receive paths according to various embodiments of the present disclosure;

FIG. 6 illustrates an example of antenna structure according to various embodiments of the present disclosure;

FIG. 7 illustrates an example of DU connected to multiple RUs through optical fiber-based fronthaul links according to various embodiments of the present disclosure;

FIG. 8 illustrates an example of an uplink processing chain according to various embodiments of the present disclosure;

FIG. 9 illustrates an example of fronthaul compression block integrated into the uplink processing chain at the RU according to various embodiments of the present disclosure;

FIG. 10 illustrates an example of sequence of steps in the fronthaul compression at the RU according to various embodiments of the present disclosure;

FIG. 11 illustrates an examples of encoding process according to various embodiments of the present disclosure;

FIG. 12 illustrates an examples of decoding process according to various embodiments of the present disclosure;

FIG. 13 illustrates another examples of decoding process according to various embodiments of the present disclosure;

FIG. 14 illustrates an example of sequence of steps in the fronthaul compression at the RU according to various embodiments of the present disclosure;

FIG. 15 illustrates an example of RU architecture and algorithms according to various embodiments of the present disclosure;

FIG. 16 illustrates an example of compression bit-width according to various embodiments of the present disclosure;

FIG. 17 illustrates an example of H.264 architecture according to various embodiments of the present disclosure;

FIG. 18 illustrates an example of color mapping according to various embodiments of the present disclosure;

FIG. 19 illustrates an example of NMSE-compression ratio tradeoff with no preprocessing according to various embodiments of the present disclosure;

FIG. 20 illustrates an example of NMSE-compression ratio tradeoff with channel inversion and channel matching according to various embodiments of the present disclosure; and

FIG. 21 illustrates a flowchart of RU method for a bit compression of uplink fronthaul data according to various embodiments of the present disclosure.

### DETAILED DESCRIPTION

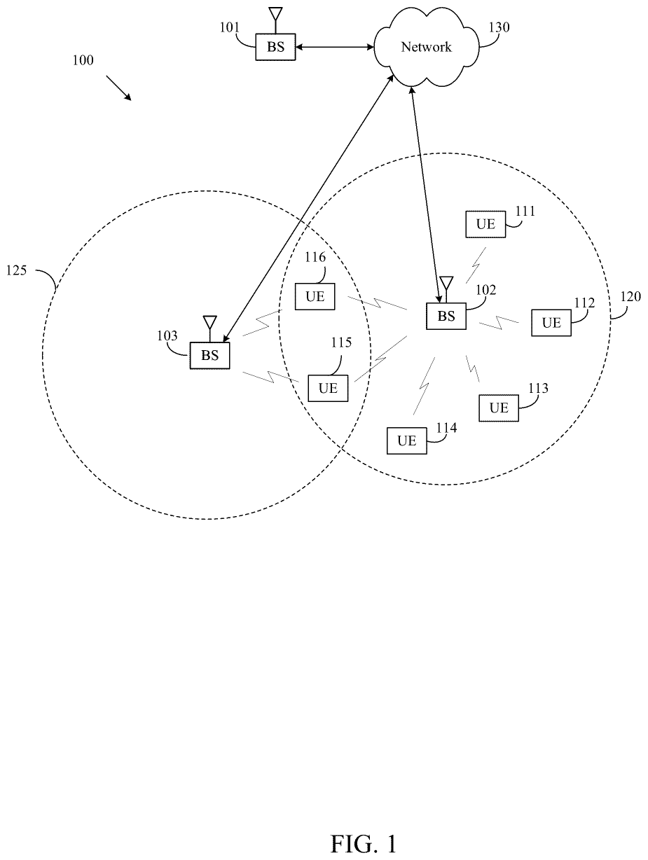

FIG. 1 through FIG. 21, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged system or device.

To meet the demand for wireless data traffic having increased since deployment of 4G communication systems and to enable various vertical applications, 5G/NR communication systems have been developed and are currently being deployed. The 5G/NR communication system is considered to be implemented in higher frequency (mmWave) bands, e.g., 28 GHz or 60GHz bands, so as to accomplish higher data rates or in lower frequency bands, such as 6 GHZ, to enable robust coverage and mobility support. To decrease propagation loss of the radio waves and increase the transmission distance, the beamforming, massive MIMO, full dimensional MIMO (FD-MIMO), array antenna, an analog beam forming, large scale antenna techniques are discussed in 5G/NR communication systems.

In addition, in 5G/NR communication systems, development for system network improvement is under way based on advanced small cells, cloud radio access networks (RANs), ultra-dense networks, device-to-device (D2D) communication, wireless backhaul, moving network, cooperative communication, coordinated multi-points (COMP), reception-end interference cancelation and the like.

The discussion of 5G systems and frequency bands associated therewith is for reference as certain embodiments of the present disclosure may be implemented in 5G systems. However, the present disclosure is not limited to 5G systems, or the frequency bands associated therewith, and embodiments of the present disclosure may be utilized in connection with any frequency band. For example, aspects of the present disclosure may also be applied to deployment of 5G communication systems, 6G or even later releases which may use terahertz (THz) bands.

FIGS. 1-3 below describe various embodiments implemented in wireless communications systems and with the use of orthogonal frequency division multiplexing (OFDM) or orthogonal frequency division multiple access (OFDMA) communication techniques. The descriptions of FIGS. 1-3 are not meant to imply physical or architectural limitations to the manner in which different embodiments may be implemented. Different embodiments of the present disclosure may be implemented in any suitably arranged communications system.

FIG. 1 illustrates an example wireless network according to various embodiments of the present disclosure. The embodiment of the wireless network shown in FIG. 1 is for illustration only. Other embodiments of the wireless network 100 could be used without departing from the scope of this disclosure.

As shown in FIG. 1, the wireless network includes a gNB 101 (e.g., base station, BS), a gNB 102, and a gNB 103. The gNB 101 communicates with the gNB 102 and the gNB 103. The gNB 101 also communicates with at least one network 130, such as the Internet, a proprietary Internet Protocol (IP) network, or other data network.

The gNB 102 provides wireless broadband access to the network 130 for a first plurality of user equipments (UEs) within a coverage area 120 of the gNB 102. The first plurality of UEs includes a UE 111, which may be located in a small business; a UE 112, which may be located in an enterprise; a UE 113, which may be a WiFi hotspot; a UE 114, which may be located in a first residence; a UE 115, which may be located in a second residence; and a UE 116, which may be a mobile device, such as a cell phone, a wireless laptop, a wireless PDA, or the like. The gNB 103 provides wireless broadband access to the network 130 for a second plurality of UEs within a coverage area 125 of the gNB 103. The second plurality of UEs includes the UE 115 and the UE 116. In some embodiments, one or more of the gNBs 101-103 may communicate with each other and with the UEs 111-116 using 5G/NR, long term evolution (LTE), long term evolution-advanced (LTE-A), WiMAX, WiFi, or other wireless communication techniques.

Depending on the network type, the term “base station” or “BS” can refer to any component (or collection of components) configured to provide wireless access to a network, such as transmit point (TP), transmit-receive point (TRP), an enhanced base station (eNodeB or eNB), a 5G/NR base station (gNB), a macrocell, a femtocell, a WiFi access point (AP), or other wirelessly enabled devices. Base stations may provide wireless access in accordance with one or more wireless communication protocols, e.g., 5G/NR 3^{rd} generation partnership project (3GPP) NR, long term evolution (LTE), LTE advanced (LTE-A), high speed packet access (HSPA), Wi-Fi 802.11a/b/g/n/ac, etc. For the sake of convenience, the terms “BS” and “TRP” are used interchangeably in this patent document to refer to network infrastructure components that provide wireless access to remote terminals. Also, depending on the network type, the term “user equipment” or “UE” can refer to any component such as “mobile station,” “subscriber station,” “remote terminal,” “wireless terminal,” “receive point,” or “user device.” For the sake of convenience, the terms “user equipment” and “UE” are used in this patent document to refer to remote wireless equipment that wirelessly accesses a BS, whether the UE is a mobile device (such as a mobile telephone or smartphone) or is normally considered a stationary device (such as a desktop computer or vending machine).

Dotted lines show the approximate extents of the coverage areas 120 and 125, which are shown as approximately circular for the purposes of illustration and explanation only. It should be clearly understood that the coverage areas associated with gNBs, such as the coverage areas 120 and 125, may have other shapes, including irregular shapes, depending upon the configuration of the gNBs and variations in the radio environment associated with natural and man-made obstructions.

As described in more detail below, one or more of the gNBs 101-103 includes circuitry, programing, or a combination thereof, to support a bit compression of uplink fronthaul data in wireless communication systems.

Although FIG. 1 illustrates one example of a wireless network, various changes may be made to FIG. 1. For example, the wireless network could include any number of gNBs and any number of UEs in any suitable arrangement. Also, the gNB 101 could communicate directly with any number of UEs and provide those UEs with wireless broadband access to the network 130. Similarly, each gNB 102-103 could communicate directly with the network 130 and provide UEs with direct wireless broadband access to the network 130. Further, the gNBs 101, 102, and/or 103 could provide access to other or additional external networks, such as external telephone networks or other types of data networks.

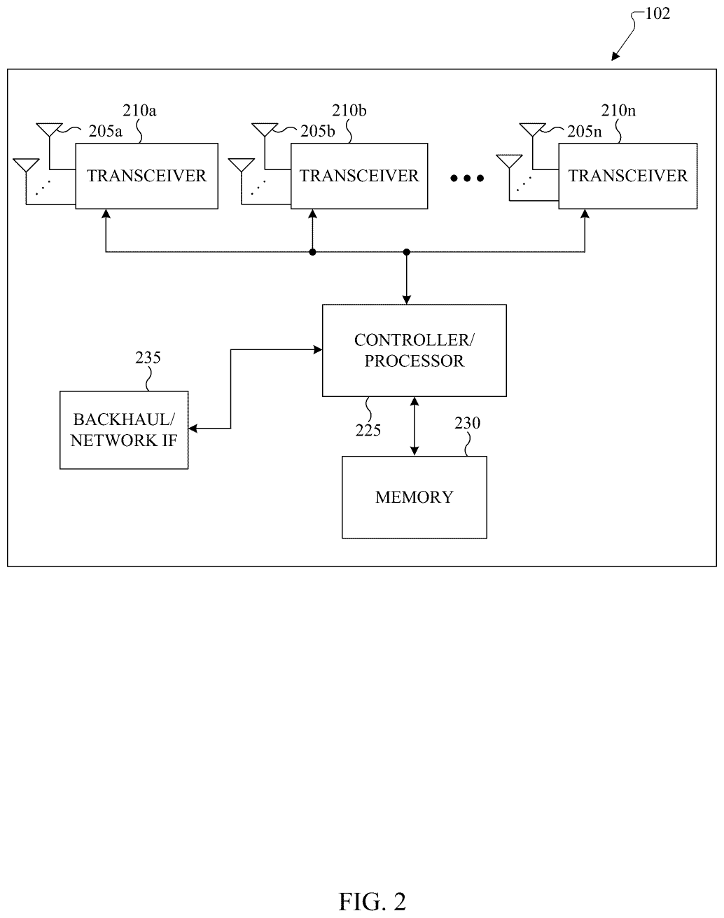

FIG. 2 illustrates an example gNB 102 according to various embodiments of the present disclosure. The embodiment of the gNB 102 illustrated in FIG. 2 is for illustration only, and the gNBs 101 and 103 of FIG. 1 could have the same or similar configuration. However, gNBs come in a wide variety of configurations, and FIG. 2 does not limit the scope of this disclosure to any particular implementation of a gNB.

As shown in FIG. 2, the gNB 102 includes multiple antennas 205a-205n, multiple transceivers 210a-210n, a controller/processor 225, a memory 230, and a backhaul or network interface 235.

The transceivers 210a-210n receive, from the antennas 205a-205n, incoming RF signals, such as signals transmitted by UEs in the network 100. The transceivers 210a-210n down-convert the incoming RF signals to generate IF or baseband signals. The IF or baseband signals are processed by receive (RX) processing circuitry in the transceivers 210a-210n and/or controller/processor 225, which generates processed baseband signals by filtering, decoding, and/or digitizing the baseband or IF signals. The controller/processor 225 may further process the baseband signals.

Transmit (TX) processing circuitry in the transceivers 210a-210n and/or controller/processor 225 receives analog or digital data (such as voice data, web data, e-mail, or interactive video game data) from the controller/processor 225. The TX processing circuitry encodes, multiplexes, and/or digitizes the outgoing baseband data to generate processed baseband or IF signals. The transceivers 210a-210n up-converts the baseband or IF signals to RF signals that are transmitted via the antennas 205a-205n.

The controller/processor 225 can include one or more processors or other processing devices that control the overall operation of the gNB 102. For example, the controller/processor 225 could control the reception of UL channel signals and the transmission of DL channel signals by the transceivers 210a-210n in accordance with well-known principles. The controller/processor 225 could support additional functions as well, such as more advanced wireless communication functions. For instance, the controller/processor 225 could support beam forming or directional routing operations in which outgoing/incoming signals from/to multiple antennas 205a-205n are weighted differently to effectively steer the outgoing signals in a desired direction. Any of a wide variety of other functions could be supported in the gNB 102 by the controller/processor 225.

The controller/processor 225 is also capable of executing programs and other processes resident in the memory 230, such as processes to support a bit compression of uplink fronthaul data in wireless communication systems. The controller/processor 225 can move data into or out of the memory 230 as required by an executing process.

The controller/processor 225 is also coupled to the backhaul or network interface 235. The backhaul or network interface 235 allows the gNB 102 to communicate with other devices or systems over a backhaul connection or over a network. The interface 235 could support communications over any suitable wired or wireless connection(s). For example, when the gNB 102 is implemented as part of a wireless communication system (such as one supporting 5G/NR, LTE, or LTE-A), the interface 235 could allow the gNB 102 to communicate with other gNBs over a wired or wireless backhaul connection. When the gNB 102 is implemented as an access point, the interface 235 could allow the gNB 102 to communicate over a wired or wireless local area network or over a wired or wireless connection to a larger network (such as the Internet). The interface 235 includes any suitable structure supporting communications over a wired or wireless connection, such as an Ethernet or transceiver.

The memory 230 is coupled to the controller/processor 225. Part of the memory 230 could include a RAM, and another part of the memory 230 could include a Flash memory or other ROM.

Although FIG. 2 illustrates one example of gNB 102, various changes may be made to FIG. 2. For example, the gNB 102 could include any number of each component shown in FIG. 2. Also, various components in FIG. 2 could be combined, further subdivided, or omitted and additional components could be added according to particular needs.

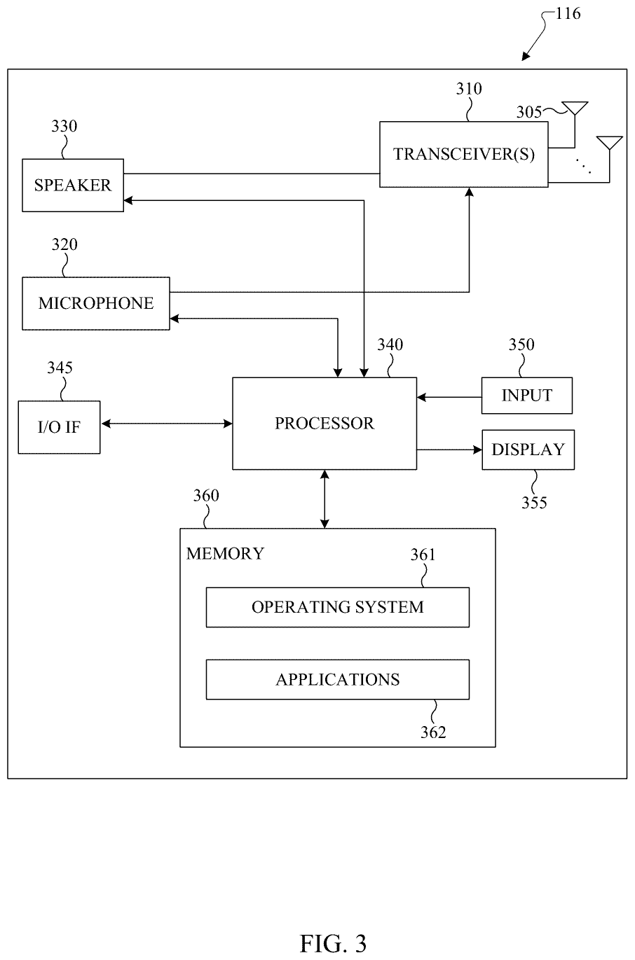

FIG. 3 illustrates an example UE 116 according to various embodiments of the present disclosure. The embodiment of the UE 116 illustrated in FIG. 3 is for illustration only, and the UEs 111-115 of FIG. 1 could have the same or similar configuration. However, UEs come in a wide variety of configurations, and FIG. 3 does not limit the scope of this disclosure to any particular implementation of a UE.

As shown in FIG. 3, the UE 116 includes antenna(s) 305, a transceiver(s) 310, and a microphone 320. The UE 116 also includes a speaker 330, a processor 340, an input/output (I/O) interface (IF) 345, an input 350, a display 355, and a memory 360. The memory 360 includes an operating system (OS) 361 and one or more applications 362.

The transceiver(s) 310 receives from the antenna 305, an incoming RF signal transmitted by a gNB of the network 100. The transceiver(s) 310 down-converts the incoming RF signal to generate an intermediate frequency (IF) or baseband signal. The IF or baseband signal is processed by RX processing circuitry in the transceiver(s) 310 and/or processor 340, which generates a processed baseband signal by filtering, decoding, and/or digitizing the baseband or IF signal. The RX processing circuitry sends the processed baseband signal to the speaker 330 (such as for voice data) or is processed by the processor 340 (such as for web browsing data).

TX processing circuitry in the transceiver(s) 310 and/or processor 340 receives analog or digital voice data from the microphone 320 or other outgoing baseband data (such as web data, e-mail, or interactive video game data) from the processor 340. The TX processing circuitry encodes, multiplexes, and/or digitizes the outgoing baseband data to generate a processed baseband or IF signal. The transceiver(s) 310 up-converts the baseband or IF signal to an RF signal that is transmitted via the antenna(s) 305.

The processor 340 can include one or more processors or other processing devices and execute the OS 361 stored in the memory 360 in order to control the overall operation of the UE 116. For example, the processor 340 could control the reception of DL channel signals and the transmission of UL channel signals by the transceiver(s) 310 in accordance with well-known principles. In some embodiments, the processor 340 includes at least one microprocessor or microcontroller.

The processor 340 can move data into or out of the memory 360 as required by an executing process. In some embodiments, the processor 340 is configured to execute the applications 362 based on the OS 361 or in response to signals received from gNBs or an operator. The processor 340 is also coupled to the I/O interface 345, which provides the UE 116 with the ability to connect to other devices, such as laptop computers and handheld computers. The I/O interface 345 is the communication path between these accessories and the processor 340.

The processor 340 is also coupled to the input 350 and the display 355m which includes for example, a touchscreen, keypad, etc., The operator of the UE 116 can use the input 350 to enter data into the UE 116. The display 355 may be a liquid crystal display, light emitting diode display, or other display capable of rendering text and/or at least limited graphics, such as from web sites.

The memory 360 is coupled to the processor 340. Part of the memory 360 could include a random-access memory (RAM), and another part of the memory 360 could include a Flash memory or other read-only memory (ROM).

Although FIG. 3 illustrates one example of UE 116, various changes may be made to FIG. 3. For example, various components in FIG. 3 could be combined, further subdivided, or omitted and additional components could be added according to particular needs. As a particular example, the processor 340 could be divided into multiple processors, such as one or more central processing units (CPUs) and one or more graphics processing units (GPUs). In another example, the transceiver(s) 310 may include any number of transceivers and signal processing chains and may be connected to any number of antennas. Also, while FIG. 3 illustrates the UE 116 configured as a mobile telephone or smartphone, UEs could be configured to operate as other types of mobile or stationary devices.

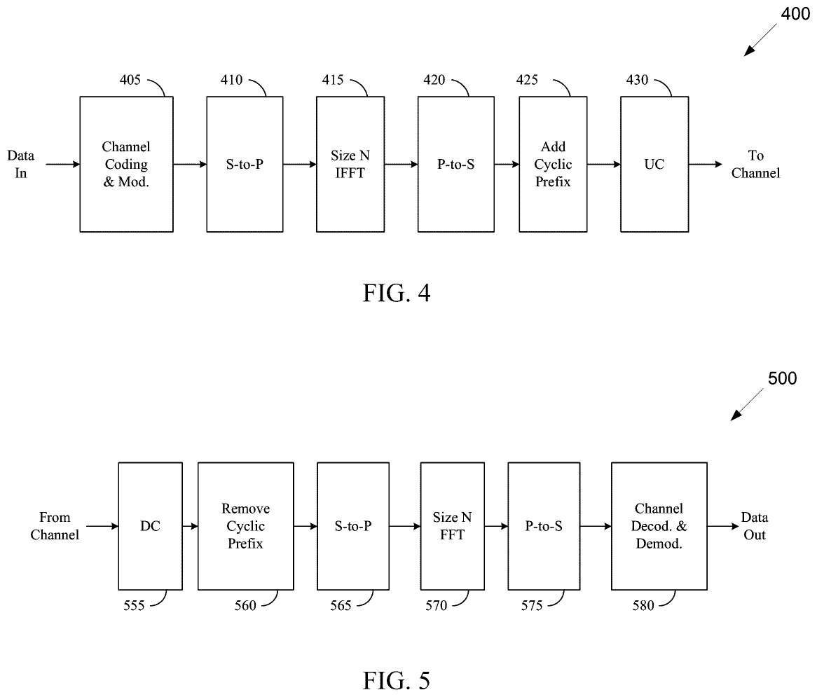

FIG. 4 and FIG. 5 illustrate example wireless transmit and receive paths according to various embodiments of the present disclosure. In the following description, a transmit path 400 may be described as being implemented in a gNB (such as the gNB 102), while a receive path 500 may be described as being implemented in a UE (such as a UE 116). However, it may be understood that the receive path 500 can be implemented in a gNB and that the transmit path 400 can be implemented in a UE. In some embodiments, the receive path 500 is configured to support a bit compression of uplink fronthaul data in wireless communication systems.

The transmit path 400 as illustrated in FIG. 4 includes a channel coding and modulation block 405, a serial-to-parallel (S-to-P) block 410, a size N inverse fast Fourier transform (IFFT) block 415, a parallel-to-serial (P-to-S) block 420, an add cyclic prefix block 425, and an up-converter (UC) 430. The receive path 500 as illustrated in FIG. 5 includes a down-converter (DC) 555, a remove cyclic prefix block 560, a serial-to-parallel (S-to-P) block 565, a size N fast Fourier transform (FFT) block 570, a parallel-to-serial (P-to-S) block 575, and a channel decoding and demodulation block 580.

As illustrated in FIG. 4, the channel coding and modulation block 405 receives a set of information bits, applies coding (such as a low-density parity check (LDPC) coding), and modulates the input bits (such as with quadrature phase shift keying (QPSK) or quadrature amplitude modulation (QAM)) to generate a sequence of frequency-domain modulation symbols.

The serial-to-parallel block 410 converts (such as de-multiplexes) the serial modulated symbols to parallel data in order to generate N parallel symbol streams, where N is the IFFT/FFT size used in the gNB 102 and the UE 116. The size N IFFT block 415 performs an IFFT operation on the N parallel symbol streams to generate time-domain output signals. The parallel-to-serial block 420 converts (such as multiplexes) the parallel time-domain output symbols from the size N IFFT block 415 in order to generate a serial time-domain signal. The add cyclic prefix block 425 inserts a cyclic prefix to the time-domain signal. The up-converter 430 modulates (such as up-converts) the output of the add cyclic prefix block 425 to an RF frequency for transmission via a wireless channel. The signal may also be filtered at baseband before conversion to the RF frequency.

A transmitted RF signal from the gNB 102 arrives at the UE 116 after passing through the wireless channel, and reverse operations to those at the gNB 102 are performed at the UE 116.

As illustrated in FIG. 5, the downconverter 555 down-converts the received signal to a baseband frequency, and the remove cyclic prefix block 560 removes the cyclic prefix to generate a serial time-domain baseband signal. The serial-to-parallel block 565 converts the time-domain baseband signal to parallel time domain signals. The size N FFT block 570 performs an FFT algorithm to generate N parallel frequency-domain signals. The parallel-to-serial block 575 converts the parallel frequency-domain signals to a sequence of modulated data symbols. The channel decoding and demodulation block 580 demodulates and decodes the modulated symbols to recover the original input data stream.

Each of the gNBs 101-103 may implement a transmit path 400 as illustrated in FIG. 4 that is analogous to transmitting in the downlink to UEs 111-116 and may implement a receive path 500 as illustrated in FIG. 5 that is analogous to receiving in the uplink from UEs 111-116. Similarly, each of UEs 111-116 may implement the transmit path 400 for transmitting in the uplink to the gNBs 101-103 and may implement the receive path 500 for receiving in the downlink from the gNBs 101-103.

Each of the components in FIG. 4 and FIG. 5 can be implemented using only hardware or using a combination of hardware and software/firmware. As a particular example, at least some of the components in FIGS. 4 and FIG. 5 may be implemented in software, while other components may be implemented by configurable hardware or a mixture of software and configurable hardware. For instance, the FFT block 570 and the IFFT block 415 may be implemented as configurable software algorithms, where the value of size N may be modified according to the implementation.

Furthermore, although described as using FFT and IFFT, this is by way of illustration only and may not be construed to limit the scope of this disclosure. Other types of transforms, such as discrete Fourier transform (DFT) and inverse discrete Fourier transform (IDFT) functions, can be used. It may be appreciated that the value of the variable N may be any integer number (such as 1, 2, 3, 4, or the like) for DFT and IDFT functions, while the value of the variable N may be any integer number that is a power of two (such as 1, 2, 4, 8, 16, or the like) for FFT and IFFT functions.

Although FIG. 4 and FIG. 5 illustrate examples of wireless transmit and receive paths, various changes may be made to FIG. 4 and FIG. 5. For example, various components in FIG. 4 and FIG. 5 can be combined, further subdivided, or omitted and additional components can be added according to particular needs. Also, FIG. 4 and FIG. 5 are meant to illustrate examples of the types of transmit and receive paths that can be used in a wireless network. Any other suitable architectures can be used to support wireless communications in a wireless network.

A unit for DL signaling or for UL signaling on a cell is referred to as a slot and can include one or more symbols. A bandwidth (BW) unit is referred to as a resource block (RB). One RB includes a number of sub-carriers (SCs). For example, a slot can have duration of one millisecond and an RB can have a bandwidth of 180 KHz and include 12 SCs with inter-SC spacing of 15 KHz. A slot can be either full DL slot, or full UL slot, or hybrid slot similar to a special subframe in time division duplex (TDD) systems.

DL signals include data signals conveying information content, control signals conveying DL control information (DCI), and reference signals (RS) that are also known as pilot signals. A gNB transmits data information or DCI through respective physical DL shared channels (PDSCHs) or physical DL control channels (PDCCHs). A PDSCH or a PDCCH can be transmitted over a variable number of slot symbols including one slot symbol. A UE can be indicated a spatial setting for a PDCCH reception based on a configuration of a value for a TCI state of a CORESET where the UE receives the PDCCH. The UE can be indicated a spatial setting for a PDSCH reception based on a configuration by higher layers or based on an indication by a DCI format scheduling the PDSCH reception of a value for a TCI state. The gNB can configure the UE to receive signals on a cell within a DL bandwidth part (BWP) of the cell DL BW.

A gNB transmits one or more of multiple types of RS including channel state information RS (CSI-RS) and demodulation RS (DMRS). A CSI-RS is primarily intended for UEs to perform measurements and provide channel state information (CSI) to a gNB. For channel measurement, non-zero power CSI-RS (NZP CSI-RS) resources are used. For interference measurement reports (IMRs), CSI interference measurement (CSI-IM) resources associated with a zero power CSI-RS (ZP CSI-RS) configuration are used. A CSI process includes NZP CSI-RS and CSI-IM resources. A UE can determine CSI-RS transmission parameters through DL control signaling or higher layer signaling, such as a radio resource control (RRC) signaling from a gNB. Transmission instances of a CSI-RS can be indicated by DL control signaling or configured by higher layer signaling. A DMRS is transmitted only in the BW of a respective PDCCH or PDSCH and a UE can use the DMRS to demodulate data or control information.

UL signals also include data signals conveying information content, control signals conveying UL control information (UCI), DMRS associated with data or UCI demodulation, sounding RS (SRS) enabling a gNB to perform UL channel measurement, and a random access (RA) preamble enabling a UE to perform random access. A UE transmits data information or UCI through a respective physical UL shared channel (PUSCH) or a physical UL control channel (PUCCH). A PUSCH or a PUCCH can be transmitted over a variable number of slot symbols including one slot symbol. The gNB can configure the UE to transmit signals on a cell within an UL BWP of the cell UL BW.

UCI includes hybrid automatic repeat request acknowledgement (HARQ-ACK) information, indicating correct or incorrect detection of data transport blocks (TBs) in a PDSCH, scheduling request (SR) indicating whether a UE has data in the buffer of UE, and CSI reports enabling a gNB to select appropriate parameters for PDSCH or PDCCH transmissions to a UE. HARQ-ACK information can be configured to be with a smaller granularity than per TB and can be per data code block (CB) or per group of data CBs where a data TB includes a number of data CBs.

A CSI report from a UE can include a channel quality indicator (CQI) informing a gNB of a largest modulation and coding scheme (MCS) for the UE to detect a data TB with a predetermined block error rate (BLER), such as a 10% BLER, of a precoding matrix indicator (PMI) informing a gNB how to combine signals from multiple transmitter antennas in accordance with a MIMO transmission principle, and of a rank indicator (RI) indicating a transmission rank for a PDSCH. UL RS includes DMRS and SRS. DMRS is transmitted only in a BW of a respective PUSCH or PUCCH transmission. A gNB can use a DMRS to demodulate information in a respective PUSCH or PUCCH. SRS is transmitted by a UE to provide a gNB with an UL CSI and, for a TDD system, an SRS transmission can also provide a PMI for DL transmission. Additionally, in order to establish synchronization or an initial higher layer connection with a gNB, a UE can transmit a physical random-access channel.

In the present disclosure, a beam is determined by either of: (1) a TCI state, which establishes a quasi-colocation (QCL) relationship between a source reference signal (e.g., synchronization signal/physical broadcasting channel (PBCH) block (SSB) and/or CSI-RS) and a target reference signal; or (2) spatial relation information that establishes an association to a source reference signal, such as SSB or CSI-RS or SRS. In either case, the ID of the source reference signal identifies the beam.

The TCI state and/or the spatial relation reference RS can determine a spatial Rx filter for reception of downlink channels at the UE, or a spatial Tx filter for transmission of uplink channels from the UE.

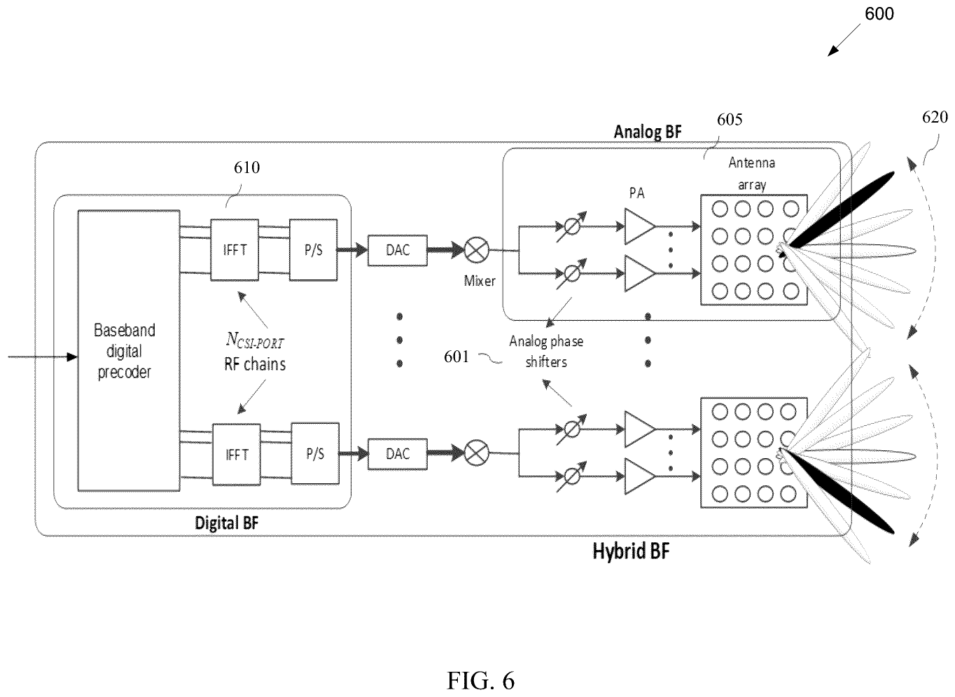

Rel.14 LTE and Rel.15 NR support up to 32 CSI-RS antenna ports which enable an eNB to be equipped with a large number of antenna elements (such as 64 or 128). In this case, a plurality of antenna elements is mapped onto one CSI-RS port. For mmWave bands, although the number of antenna elements can be larger for a given form factor, the number of CSI-RS ports—which can correspond to the number of digitally precoded ports—tends to be limited due to hardware constraints (such as the feasibility to install a large number of ADCs/DACs at mmWave frequencies) as illustrated in FIG. 6.

FIG. 6 illustrates an example antenna structure 600 according to various embodiments of the present disclosure. An embodiment of the antenna structure 600 shown in FIG. 6 is for illustration only.

In this case, one CSI-RS port is mapped onto a large number of antenna elements which can be controlled by a bank of analog phase shifters 601. One CSI-RS port can then correspond to one sub-array which produces a narrow analog beam through analog beamforming 605. This analog beam can be configured to sweep across a wider range of angles 620 by varying the phase shifter bank across symbols or subframes. The number of sub-arrays (equal to the number of RF chains) is the same as the number of CSI-RS ports N_{CSI-PORT}. A digital beamforming unit 610 performs a linear combination across N_{CSI-PORT} analog beams to further increase precoding gain. While analog beams are wideband (hence not frequency-selective), digital precoding can be varied across frequency sub-bands or resource blocks. Receiver operation can be conceived analogously.

Since the aforementioned system utilizes multiple analog beams for transmission and reception (wherein one or a small number of analog beams are selected out of a large number, for instance, after a training duration—to be performed from time to time), the term “multi-beam operation” is used to refer to the overall system aspect. This includes, for the purpose of illustration, indicating the assigned DL or UL TX beam (also termed “beam indication”), measuring at least one reference signal for calculating and performing beam reporting (also termed “beam measurement” and “beam reporting,” respectively), and receiving a DL or UL transmission via a selection of a corresponding RX beam.

The aforementioned system is also applicable to higher frequency bands such as >52.6G Hz. In this case, the system can employ only analog beams. Due to the O2 absorption loss around 60 GHz frequency (˜10 dB additional loss @100 m distance), larger number of and sharper analog beams (hence larger number of radiators in the array) may be needed to compensate for the additional path loss.

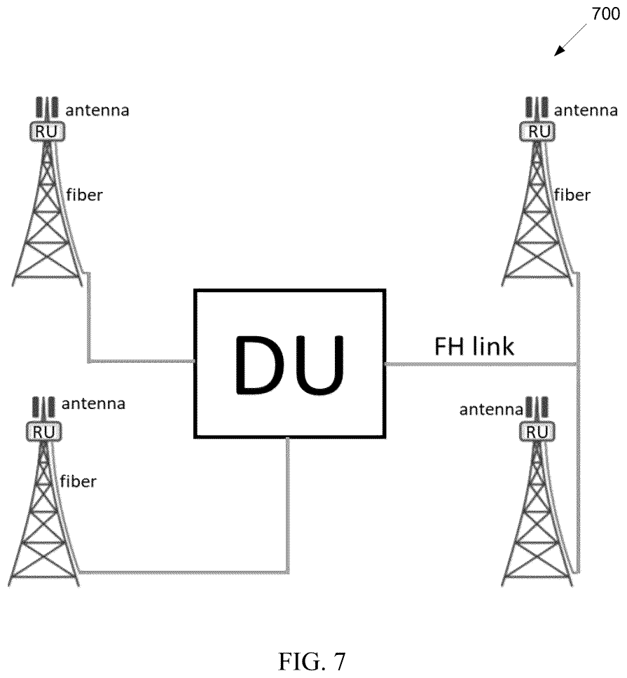

FIG. 7 illustrates an example of DU connected to multiple RUs through optical fiber-based fronthaul links 700 according to various embodiments of the present disclosure. An embodiment of the DU connected to multiple RUs through optical fiber-based fronthaul links 700 shown in FIG. 7 is for illustration only.

FIG. 7 depicts a distributed unit (DU) connected to multiple radio units (Rus) through optical fiber-based fronthaul links. The fronthaul carries uplink data from RU to DU and downlink data from DU to RU. For a 100 MHz X-MIMO system with 256 ports and 30 kHz subcarrier spacing, the fronthaul bandwidth requirement for uplink is more than 500 Gbps if data is required to be transmitted from all ports without compression.

The RU may be implemented as a UE (e.g., as illustrated in 111-116) or a BS (e.g., as illustrated in 101-103).

The RU may be implemented as a UE (e.g., as illustrated in FIG. 3) and a BS (e.g., as illustrated in FIG. 4).

The DU may be implemented as a UE (e.g., as illustrated in 111-116) or a BS (e.g., as illustrated in 101-103).

The DU may be implemented as a UE (e.g., as illustrated in FIG. 3) and a BS (e.g., as illustrated in FIG. 4).

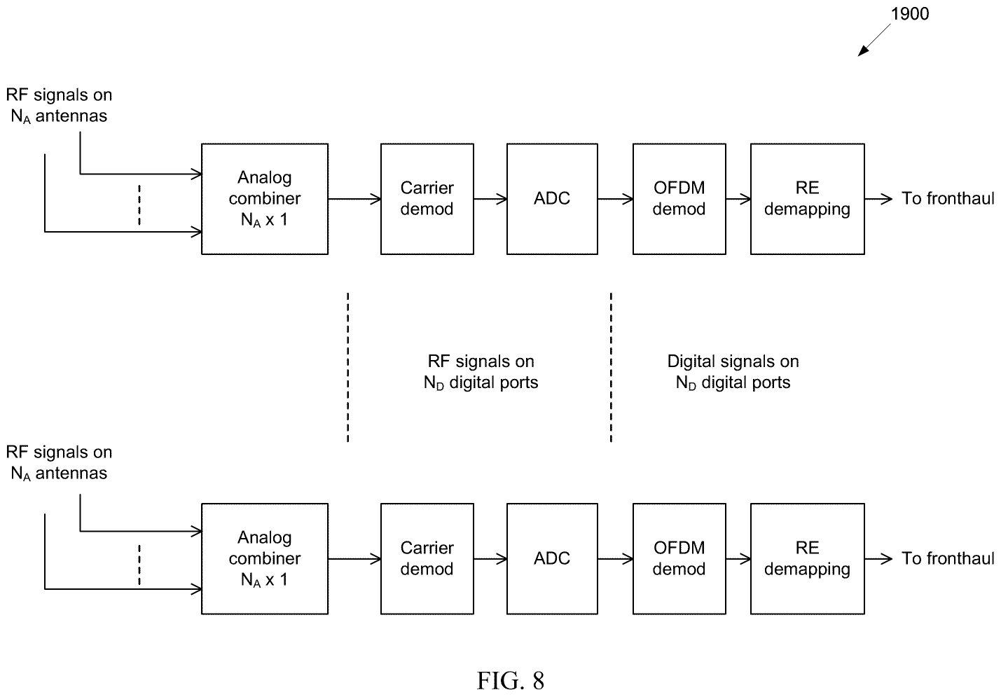

FIG. 8 illustrates an example of uplink processing chain 800 according to various embodiments of the present disclosure. An embodiment of the uplink processing chain 800 shown in FIG. 8 is for illustration only.

FIG. 8 depicts an uplink processing chain, where uplink antenna data is passed through the RF frontend and analog combiners, and N_{D} digital streams are transmitted over the fronthaul to the DU. In 5G-advanced or 6G communications, extremely large number of antennas (e.g., N_{T}=2048) and large number of digital ports (N_{D}≥256) are expected to be used. Uplink user data from all these ports have to be sent over the fronthaul links, leading to large capacity requirements on the fronthaul.

In the present disclosure, an invertible pre-processing at RU is provided to introduce similarity in data for aiding in entropy compression.

In the present disclosure, a mapping uplink wireless data to red, green, and blue (RGB) values is provided to optimize video compression performance.

In the present disclosure, compression at RU are determined based on: (1) preprocessing: invertible preprocessing is performed at RU to facilitate bit compression; (2) (I, Q)→(R, G, B) mapping: bit domain transformation maps I/Q data to color domain; (3) residuals: data is processed in blocks of size N (user-defined parameter) and difference coding is performed over the blocks (successive differences are taken over the blocks, with the first processed block left unchanged); (4) scaling, and quantization: integer transform and quantization (least significant bit (LSB) truncation) is performed on the data bits to increase compressibility. This step introduces loss in the compression; and (5) entropy coding: data is further compressed losslessly using entropy coding approaches such as context-adaptive variable length coding (CAVLC), context-adaptive binary arithmetic coding (CABAC), or Huffman coding.

In the present disclosure, the coded bits at the end of step 5 are transmitted over the fronthaul links. Decompression at DU are determined based on: (1) decoding bits: coded bits are decoded; (2) inverse scaling: scaling to recover the residuals; (3) accumulate: block i is recovered by adding residual i to recovered block (i−1) for i=2, 3, . . . ; and (4) (R, G, B)→(I, Q) mapping: bit domain transformation maps recover color domain data, i.e., (R, G, B), back to I/Q domain.

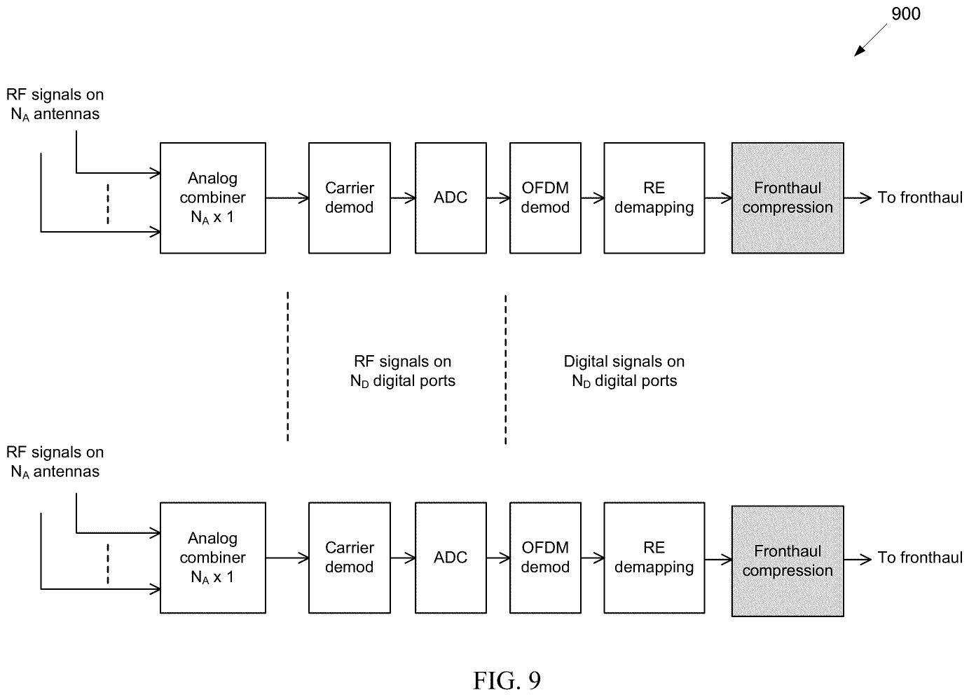

FIG. 9 illustrates an example of fronthaul compression block integrated into the uplink processing chain at the RU 900 according to various embodiments of the present disclosure. An embodiment of the fronthaul compression block integrated into the uplink processing chain at the RU 900 shown in FIG. 9 is for illustration only.

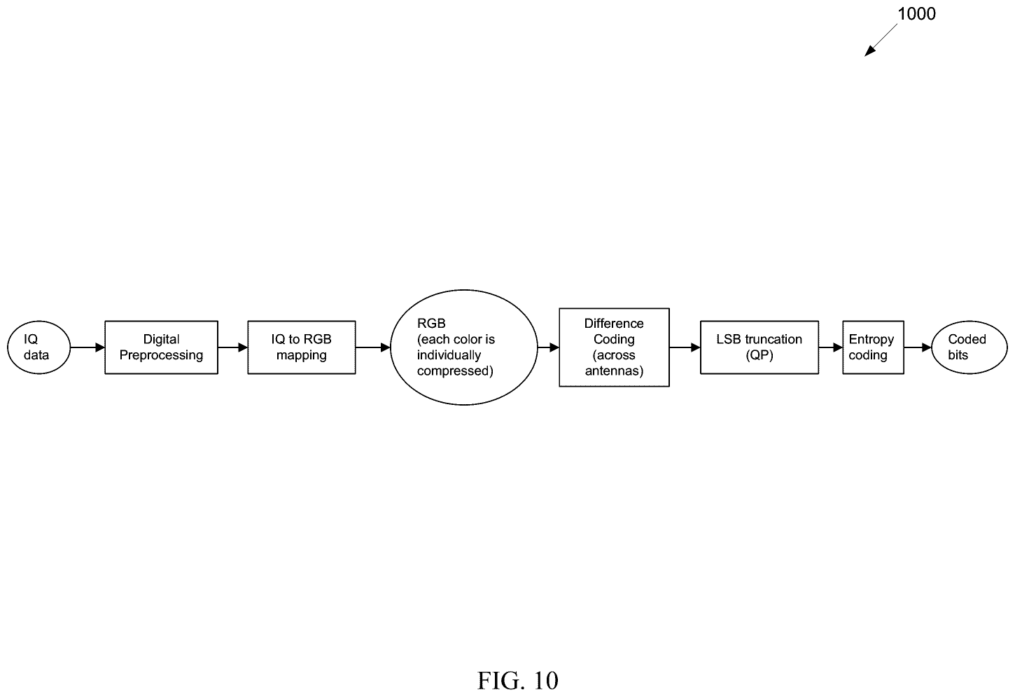

FIG. 10 illustrates an example of sequence of steps in the fronthaul compression at the RU 1000 according to various embodiments of the present disclosure. An embodiment of the sequence of steps in the fronthaul compression at the RU 1000 shown in FIG. 10 is for illustration only. FIG. 10 depicts the sequence of steps in the fronthaul compression at the RU for this embodiment. Some of the blocks shown in FIG. 10 may be omitted in certain embodiments.

In the present disclosure, an RU processing is provided.

In one embodiment, a digital preprocessing is provided. In the digital preprocessing, the raw data from the antenna ports are digitally pre-processed using channel estimates to induce correlation across the antenna ports. The pre-processing operation may satisfy 3 conditions: (1) invertibility, (2) transparency, and (3) similarity. The operation may be invertible to ensure no information is lost. The operation may be transparent, so the DU can process its data without any knowledge of the pre-processing. The operation may, finally, induce the correlation needed for the data compression.

Any preprocessing which is a full rank square matrix multiplication may satisfy the first 2 requirements. The matrix may be appropriately chosen to meet the third requirement.

In one embodiment, channel inversion method in which the channel effect is removed is used. The transmitted signal is available as a repetition across multiple antenna ports. The data at the antenna digital port (N_{D}) for a given resource element is given by Y as shown below:

$$[ \begin{matrix}{Y}_{1} \\ ⋮ \\ {Y}_{{N}_{D}}\end{matrix} ] = [ \begin{matrix}{H}_{1 , 1} & … & {H}_{1 , L} \\ ⋮ & ⋱ & ⋮ \\ {H}_{{N}_{D} , 1} & … & {h}_{{N}_{D} , L}\end{matrix} ] [ \begin{matrix}{X}_{1} \\ ⋮ \\ {X}_{L}\end{matrix} ] + [ \begin{matrix}{I}_{1} \\ ⋮ \\ {I}_{{N}_{D}}\end{matrix} ] + [ \begin{matrix}{N}_{1} \\ ⋮ \\ {N}_{{N}_{D}}\end{matrix} ]$$

or Y=HX+I+N where H is the channel matrix, L is the number of uplink data layers, X is the transmitted signal, I is the intercell interference and N is the thermal noise. A channel submatrix (Hᵢ) for i=1,2, . . . , N_{D}/L as

$${H}_{i} = [ \begin{matrix}{H}_{( i - 1 ) * L + 1 , 1} & … & {H}_{( i - 1 ) * L + 1 , L} \\ ⋮ & ⋱ & ⋮ \\ {H}_{( i - 1 ) * L + L , 1} & … & {H}_{( i - 1 ) * L + L , L}\end{matrix} ]$$

is determined.

Now, the channel inversion operation is carried out as

$$[ \begin{matrix}{H}_{1}^{- 1} & … & 0 \\ ⋮ & ⋱ & ⋮ \\ 0 & … & {H}_{{N}_{D} / L}^{- 1}\end{matrix} ] [ \begin{matrix}{Y}_{1} \\ ⋮ \\ {Y}_{{N}_{D}}\end{matrix} ] =$$

$$[ \begin{matrix}{H}_{1}^{- 1} & … & 0 \\ ⋮ & ⋱ & ⋮ \\ 0 & … & {H}_{{N}_{D} / L}^{- 1}\end{matrix} ] [ \begin{matrix}{H}_{1 , 1} & … & {H}_{1 , L} \\ ⋮ & ⋱ & ⋮ \\ {H}_{{N}_{D} , 1} & … & {H}_{{N}_{D} , L}\end{matrix} ] [ \begin{matrix}{X}_{1} \\ ⋮ \\ {X}_{L}\end{matrix} ] +$$

$$[ \begin{matrix}{H}_{1}^{- 1} & … & 0 \\ ⋮ & ⋱ & ⋮ \\ 0 & … & {H}_{{N}_{D} / L}^{- 1}\end{matrix} ] ( [ \begin{matrix}{I}_{1} \\ ⋮ \\ {I}_{{N}_{D}}\end{matrix} ] + [ \begin{matrix}{N}_{1} \\ ⋮ \\ {N}_{{N}_{D}}\end{matrix} ] ) ⟹ [ \begin{matrix}{\tilde{Y}}_{1} \\ ⋮ \\ {\tilde{Y}}_{L} \\ {\tilde{Y}}_{L + 1} \\ ⋮ \\ {\tilde{Y}}_{{N}_{D}}\end{matrix} ] = [ \begin{matrix}{X}_{1} \\ ⋮ \\ {X}_{L} \\ {X}_{1} \\ ⋮ \\ {X}_{L}\end{matrix} ] + [ \begin{matrix}{Z}_{1} \\ ⋮ \\ {Z}_{L} \\ {Z}_{L + 1} \\ ⋮ \\ {Z}_{{N}_{D}}\end{matrix} ] or$$

$$[ \begin{matrix}{\tilde{Y}}_{1} & … & {\tilde{Y}}_{{N}_{D} + 1 - L} \\ ⋮ & ⋱ & ⋮ \\ {\tilde{Y}}_{L} & … & {\tilde{Y}}_{{N}_{D}}\end{matrix} ] = [ \begin{matrix}{X}_{1} & … & {X}_{1} \\ ⋮ & ⋱ & ⋮ \\ {X}_{L} & … & {X}_{L}\end{matrix} ] + [ \begin{matrix}{Z}_{1} & … & {Z}_{{N}_{D} + 1 - L} \\ ⋮ & ⋱ & ⋮ \\ {Z}_{L} & … & {Z}_{{N}_{D}}\end{matrix} ] .$$

This gives rise to repetition of the data symbol for every layer. To have an estimate of the clean signal, the first column is replaced with the average of the columns:

$$[ \begin{matrix}{\tilde{Y}}_{1} & … & {\tilde{Y}}_{{N}_{D} + 1 - L} \\ ⋮ & ⋱ & ⋮ \\ {\tilde{Y}}_{L} & … & {\tilde{Y}}_{{N}_{D}}\end{matrix} ] [ \begin{matrix}L / {N}_{D} & … & 0 \\ ⋮ & ⋱ & ⋮ \\ L / {N}_{D} & … & 1\end{matrix} ] = [ \begin{matrix}{X}_{1} & … & {X}_{1} \\ ⋮ & ⋱ & ⋮ \\ {X}_{L} & … & {X}_{L}\end{matrix} ] [ \begin{matrix}L / {N}_{D} & … & 0 \\ ⋮ & ⋱ & ⋮ \\ L / {N}_{D} & … & 1\end{matrix} ] +$$

$$[ \begin{matrix}{Z}_{1} & … & {Z}_{{N}_{D} + 1 - L} \\ ⋮ & ⋱ & ⋮ \\ {Z}_{L} & … & {Z}_{{N}_{D}}\end{matrix} ] [ \begin{matrix}L / {N}_{D} & … & 0 \\ ⋮ & ⋱ & ⋮ \\ L / {N}_{D} & … & 1\end{matrix} ] ⟹ A := [ \begin{matrix}{A}_{1} & … & {A}_{{N}_{D} + 1 - L} \\ ⋮ & ⋱ & ⋮ \\ {A}_{L} & … & {A}_{{N}_{D}}\end{matrix} ] =$$

$$[ \begin{matrix}{X}_{1} & … & {X}_{1} \\ ⋮ & ⋱ & ⋮ \\ {X}_{L} & … & {X}_{L}\end{matrix} ] + [ \begin{matrix}{\tilde{Z}}_{1} & … & {Z}_{{N}_{D} + 1 - L} \\ ⋮ & ⋱ & ⋮ \\ {\tilde{Z}}_{L} & … & {Z}_{{N}_{D}}\end{matrix} ] .$$

In another embodiment, a channel matching method in which the channel phase is removed is used. The transmitted signal is combined from multiple antennas and is available as an approximate repetition across multiple antenna ports. The data at the antenna digital port is given by

$$Y : [ \begin{matrix}{Y}_{1} \\ ⋮ \\ {Y}_{{N}_{D}}\end{matrix} ] = [ \begin{matrix}{H}_{1 , 1} & … & {H}_{1 , L} \\ ⋮ & ⋱ & ⋮ \\ {H}_{{N}_{D} , 1} & … & {H}_{{N}_{D} , L}\end{matrix} ] [ \begin{matrix}{X}_{1} \\ ⋮ \\ {X}_{L}\end{matrix} ] + [ \begin{matrix}{I}_{1} \\ ⋮ \\ {I}_{{N}_{D}}\end{matrix} ] + [ \begin{matrix}{N}_{1} \\ ⋮ \\ {N}_{{N}_{D}}\end{matrix} ] .$$

Now, the channel matching operation is carried out as:

$$[ \begin{matrix}{H}_{1}^{*} & … & 0 \\ ⋮ & ⋱ & ⋮ \\ 0 & … & {H}_{{N}_{D} / L}^{*}\end{matrix} ] [ \begin{matrix}{Y}_{1} \\ ⋮ \\ {Y}_{{N}_{D}}\end{matrix} ] =$$

$$[ \begin{matrix}{H}_{1}^{*} & … & 0 \\ ⋮ & ⋱ & ⋮ \\ 0 & … & {H}_{{N}_{D} / L}^{*}\end{matrix} ] [ \begin{matrix}{H}_{1 , 1} & … & {H}_{1 , L} \\ ⋮ & ⋱ & ⋮ \\ {H}_{{N}_{D} , 1} & … & {H}_{{N}_{D} , L}\end{matrix} ] [ \begin{matrix}{X}_{1} \\ ⋮ \\ {X}_{L}\end{matrix} ] + [ \begin{matrix}{H}_{1}^{*} & … & 0 \\ ⋮ & ⋱ & ⋮ \\ 0 & … & {H}_{{N}_{D} / L}^{*}\end{matrix} ]$$

$$( [ \begin{matrix}{I}_{1} \\ ⋮ \\ {I}_{{N}_{D}}\end{matrix} ] + [ \begin{matrix}{N}_{1} \\ ⋮ \\ {N}_{{N}_{D}}\end{matrix} ] ) ⟹ [ \begin{matrix}{\tilde{Y}}_{1} \\ ⋮ \\ {\tilde{Y}}_{L} \\ {\tilde{Y}}_{L + 1} \\ ⋮ \\ {\tilde{Y}}_{{N}_{D}}\end{matrix} ] = [ \begin{matrix}{H}_{1}^{*} {H}_{1} \\ ⋮ \\ {H}_{{N}_{D} / L}^{*} {H}_{{N}_{D} / L}\end{matrix} ] [ \begin{matrix}{X}_{1} \\ ⋮ \\ {X}_{L}\end{matrix} ] + [ \begin{matrix}{Z}_{1} \\ ⋮ \\ {Z}_{L} \\ {Z}_{L + 1} \\ ⋮ \\ {Z}_{{N}_{D}}\end{matrix} ] or$$

$$[ \begin{matrix}{\tilde{Y}}_{1} & … & {\tilde{Y}}_{{N}_{D} + 1 - L} \\ ⋮ & ⋱ & ⋮ \\ {\tilde{Y}}_{L} & … & {\tilde{Y}}_{{N}_{D}}\end{matrix} ] = [ \begin{matrix}{H}_{1}^{*} {H}_{1} X & … & {H}_{\frac{{N}_{D}}{L}}^{*} {H}_{\frac{{N}_{D}}{L}} X\end{matrix} ] + [ \begin{matrix}{Z}_{1} & … & {Z}_{{N}_{D} + 1 - L} \\ ⋮ & ⋱ & ⋮ \\ {Z}_{L} & … & {Z}_{{N}_{D}}\end{matrix} ] .$$

This gives rise to repetition of similar data symbols for every layer. To have a clean estimate of the signal, the first column is replaced with the average of the columns:

$$[ \begin{matrix}{\tilde{Y}}_{1} & … & {\tilde{Y}}_{{N}_{D} + 1 - L} \\ ⋮ & ⋱ & ⋮ \\ {\tilde{Y}}_{L} & … & {\tilde{Y}}_{{N}_{D}}\end{matrix} ] [ \begin{matrix}L / {N}_{D} & … & 0 \\ ⋮ & ⋱ & ⋮ \\ L / {N}_{D} & … & 1\end{matrix} ] =$$

$$[ \begin{matrix}{H}_{1}^{*} {H}_{1} X & … & {H}_{\frac{{N}_{D}}{L}}^{*} {H}_{\frac{{N}_{D}}{L}} X\end{matrix} ] [ \begin{matrix}L / {N}_{D} & … & 0 \\ ⋮ & ⋱ & ⋮ \\ L / {N}_{D} & … & 1\end{matrix} ] +$$

$$[ \begin{matrix}{Z}_{1} & … & {Z}_{{N}_{D} + 1 - L} \\ ⋮ & ⋱ & ⋮ \\ {Z}_{L} & … & {Z}_{{N}_{D}}\end{matrix} ] [ \begin{matrix}L / {N}_{D} & … & 0 \\ ⋮ & ⋱ & ⋮ \\ L / {N}_{D} & … & 1\end{matrix} ] ⟹ A := [ \begin{matrix}{A}_{1} & … & {A}_{{N}_{D} + 1 - L} \\ ⋮ & ⋱ & ⋮ \\ {A}_{L} & … & {A}_{{N}_{D}}\end{matrix} ] =$$

$$[ \begin{matrix}\tilde{{H}_{1}^{*} {H}_{1}} X & … & {H}_{\frac{{N}_{D}}{L}}^{*} {H}_{\frac{{N}_{D}}{L}} X\end{matrix} ] + [ \begin{matrix}{\tilde{Z}}_{1} & … & {Z}_{{N}_{D} + 1 - L} \\ ⋮ & ⋱ & ⋮ \\ {\tilde{Z}}_{L} & … & {Z}_{{N}_{D}}\end{matrix} ] .$$

In one embodiment, each row of matrix A represents a unique data layer. Each resource element, including a single subcarrier and an OFDM symbol, corresponds to one realization of A. Hence, the dimension of the data in one slot is L*N_{D}/L*N_{SC}*N_{OS}, where N_{SC} is the number of subcarriers and N_{OS} is the number of OFDM symbols in a slot. The next steps are performed in parallel for each OFDM symbol and data layer. In such operation, the data corresponds to an OFDM symbol and data layer as a stream where each stream has dimension N_{D}/L*N_{SC}.

The choice of the specific digital preprocessing to be performed is indicated by the DU to the RU through control signaling.

In one embodiment, (I, Q)→(R, G, B) mapping is provided. In such embodiment, various transformations can be used to transform I/Q data into color domain data. These data samples in each stream are represented using 12 bits for I component and 12 bits for Q component.

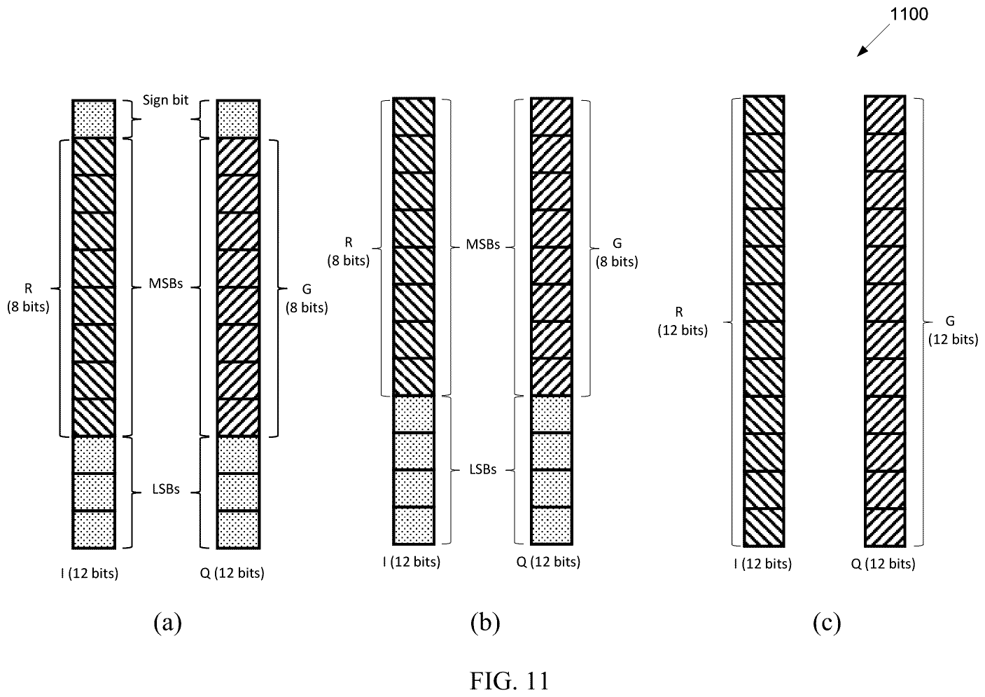

In one embodiment, as shown in FIG. 11 (e.g., (a) of FIG. 11), the mapping follows for signed values of I, Q: (a) R=I(2:9); (b) G=Q(2:9); and (c) B=[I(1, 10, 11, 12) Q(1, 10, 11, 12)].

In one embodiment, as shown in FIG. 11 (e.g., (b) od FIG. 11), the mapping follows for unsigned values of I, Q: (a) R=I(1:8); (b) G=Q(1:8); and (c) B=[I(9:12) Q(9:12)].

In one embodiment, as shown in FIG. 11 (e.g., (c) of FIG. 11), the mapping follows for unsigned values of I, Q: (a) R=I and (b) G=Q.

The choice of the (I, Q) to (R, G, B) mapping used is indicated by the DU to the RU through control signaling.

In one embodiment, a difference coding is provided. In such embodiment, each stream of color domain data (for example, R, G, or B) split into data blocks of size 1*N including data in a single port and N subcarriers. Block a_{i,j} denotes data of port j and subcarriers from (i−1)N+1 to iN. In such embodiment, the residuals b_{i,j} is provided as b_{i,1}=a_{i,1} and b_{i,j}=a_{i,j}−a_{i,1} for j=2,3, . . . , N_{D}/L for j=1,2, . . . , N_{SC}/N.

In some embodiments, the difference coding step may be skipped and the data may be directly passed to the following processing step. The choice of whether or not to perform difference coding is indicated by the DU to the RU using a 1-bit flag.

In one embodiment, transform and scaling are provide. In such embodiment, after taking residuals, each block of data is transformed and scaled. In one embodiment, the residuals are transformed using a scaled discrete cosine transform (DCT). In another embodiment, along with using (I, Q)→(R, G, B) mapping type 3, the I/Q residuals are transformed using a scaled discrete Fourier transform (DFT) or fast Fourier transform (FFT). In yet another embodiment, the integer transform is taken to be identity, i.e., no transformation is performed.

After the transformation, each block is then scaled down and quantized leading to a many-to-one mapping. This reduces the entropy of the data and has the effect of a lossy compression. It may be denoted, by QP, the number of bits to be truncated from the residuals. For e.g., QP=2 denotes to 2 LSB bits being truncated from the residual which corresponds to scaling by ¼. Adjusting QP according to the data statistics may lead to a good trade-off between compression ratio and compression loss.

The choice of the integer transform to be used is indicated by the DU to the RU through control signaling.

In some embodiments, the value of QP to be used is indicated to the RU by the DU through control signaling. In another embodiment, the value of QP is selected autonomously by the RU and indicated as a part of the section extensions or as a header to the compressed bit stream transmitted by the RU to the DU.

In one embodiment, an entropy coding is provided. In such embodiment, a variant of context-adaptive variable length coding (CAVLC) is used to compress the data losslessly into bits. The encoding process works sequentially on blocks of data of size N and includes several steps as depicted in FIG. 11.

FIG. 11 illustrates an examples of encoding process 1100 according to various embodiments of the present disclosure. An embodiment of encoding process 1100 shown in FIG. 11 is for illustration only.

In the first step, the total number n of nonzero coefficients (n≤N) and total number m of trailing 1 s (m≤M) are encoded using a prefix-free code that maps each tuple (m, n) into a sequence of bits using a pre-determined lookup table.

In the second step, the signs of the trailing 1 s are encoded using m sign bits.

In the third step, the magnitude and sign of the remaining nonzero coefficients aᵢ other than the trailing 1 s are encoded in reverse order. One embodiment of this encoding is described in TABLE 1.

In the fourth step, the total number of zeros before the last nonzero coefficient in the block is encoded using a prefix-free code that maps the number of nonzero coefficients to a sequence of bits using a pre-determined lookup table.

In the fifth step, each run of zeros between two consecutive nonzero coefficients (i.e., the number of zeros between two nonzero coefficients) and the number of zeros remaining, are jointly encoded using a prefix-free code that maps to a sequence of bits using a pre-determined lookup table.

In another embodiment, Huffman coding is used to encode each data sample. A prefix-free code is generated offline that maps each data sample to a sequence of bits using a pre-determined lookup table. Multiple lookup tables may be used, the choice of lookup table being a function of the operating SNR, the scenario (line of sight (LOS)/none-LOS (NLOS) and number of data layers), as well as the choice of RU preprocessing. In one embodiment, lookup tables could be refreshed/updated as more data streams are observed.

In yet another embodiment, an entropy coding is skipped and data samples are converted to bit streams using uniform coding. For example, data samples ranging from −2048 to +2047 may be uniformly encoded using 12 bits each.

The specific option for entropy coding may be indicated by the DU to the RU using control signaling. In another embodiment, the RU may autonomously decide whether to perform entropy coding or uniform binary encoding and indicate the decision through 1 bit in the header.

The choice of lookup tables for entropy coding is indicated by the DU to the RU through control signaling.

TABLE 1
Encoding levels

BEGIN
i ← m + 1;
if n > 10 && m < M
l_{S} ← 1;
else
l_{S} ← 0;
end if
while i ≤ n do
${b}_{i} = \{ \begin{matrix}- 2 {a}_{i} - 1 , & {a}_{i} < 0 \\ 2 {a}_{i} - 2 , & {a}_{i} > 0\end{matrix}$
if i = = m + 1 && m < 3
bᵢ ← bᵢ − 2
end if
$if ⌊ \frac{{b}_{i}}{{2}^{{l}_{S}}} ⌋ < 14$
$Prefix ← ⌊ \frac{{b}_{i}}{{2}^{{l}_{S}}} ⌋ 1 s$
Suffix ← l_{S} LSB of bᵢ
elseif lₛ = = 0 && 14 ≤ bᵢ < 30
Prefix ← 14 1s
Suffix ← 4 LSB of bᵢ − 14
$elseif {l}_{S} > 0 \&\& ⌊ \frac{{b}_{i}}{{2}^{{l}_{S}}} ⌋ == 14$
Prefix ← 14 1s
Suffix ← l_{S} LSB of bᵢ
else
Prefix ← 15 1s
Suffix ← 12 LSB of (bᵢ − 15 · [symbol] )
${\tilde{l}}_{S} = \{ \begin{matrix}{l}_{S} , & {l}_{S} > 0 \\ 1 , & {l}_{S} = 0\end{matrix}$
end if
if l_{S} = = 0
l_{S} ← l_{S} + 1
end if
if |aᵢ| > 3 · 2^{l}^{_{S}}⁻¹ && l_{S} < 6
l_{S} ← l_{S} + 1
end if
i ← i + 1
end while
RETURN
The level for each i is encoded as [Prefix | Suffix].

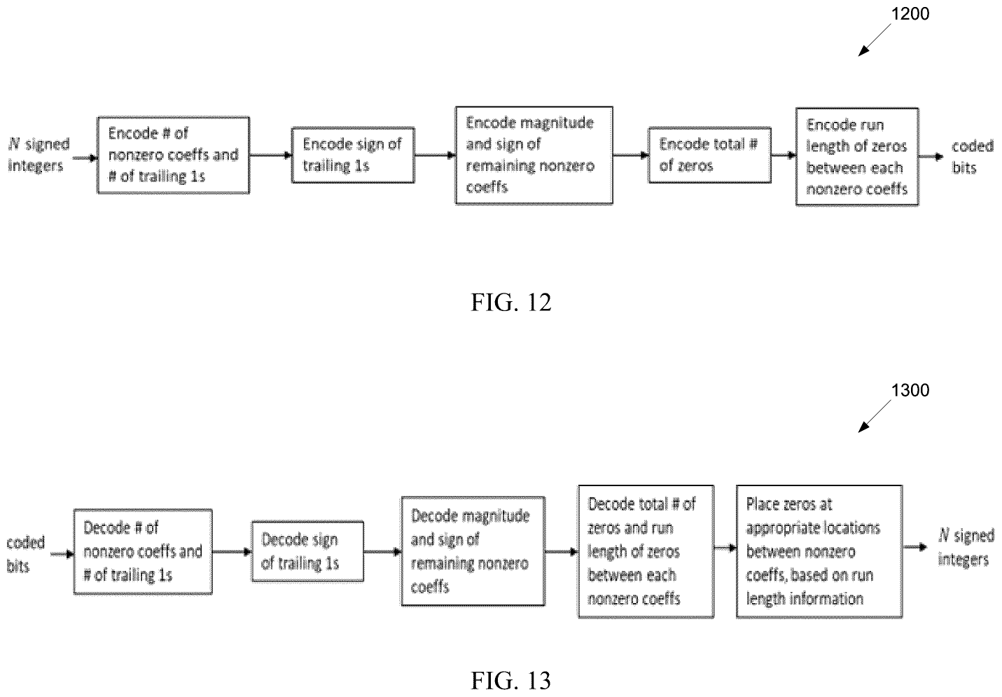

FIG. 12 illustrates an examples of decoding process 1200 according to various embodiments of the present disclosure. An embodiment of the decoding process 1200 shown in FIG. 12 is for illustration only.

In one embodiment, a DU processing is provided.

The decoding follows a similar sequence of steps as the encoding, as depicted in FIG. 12.

In the first step, the total number n of nonzero coefficients (n≤N) and total number m of trailing 1 s (m≤M) are decoded using the relevant lookup table.

In the second step, the signs of the trailing Is are decoded using the following m bits.

In the third step, the magnitude and sign of the remaining nonzero coefficients aᵢ other than the trailing 1 s are decoded. One embodiment of this encoding is explained in TABLE 2.

In the fourth step, the total number of zeros before the last nonzero coefficient in the block is decoded using the relevant lookup table.

In the fifth step, each run of zeros between two consecutive nonzero coefficients (i.e., the number of zeros between two nonzero coefficients) and the number of zeros remaining, are decoded. Based on the run length information, appropriate numbers of zeros are placed between the decoded nonzero coefficients to recover the length N block.

In another embodiment, if Huffman coding is used to encode each data sample, decoding is performed sample by sample using the corresponding lookup table.

TABLE 2
Decoding level

```
BEGIN
i ← m + 1;
if n > 10 && m < M
  l_{S} ← 1;
else
  l_{S} ← 0;
end if
while i ≤ n do
  Decode PrefixLength as number of consecutive 1s in bitstream
  if PrefixLength < 14 && l_{S} == 0
  SuffixLength ← 0
  elseif PrefixLength == 14 && l_{S} == 0
  SuffixLength ← 4
  elseif PrefixLength ≥ 15
  SuffixLength ← PrefixLength − 3
  else
  SuffixLength ← l_{S}
  end if
  bᵢ ← PrefixLength · 2^{SuffixLength} + Suffix
  if bᵢ is odd
  aᵢ ← −(bᵢ + 1)/2
  else
  aᵢ ← (bᵢ + 2)/2
  end if
  if l_{S} = 0
  l_{S} ← l_{S} + 1
  end if
  if |aᵢ| > 3 · 2^{l}^{_{S}}⁻¹ && l_{S} < 6
  l_{S} ← l_{S} + 1
  end if
  i ← i + 1
end while
RETURN
```

In one embodiment, inverse integer transform and scaling are provided. In such embodiment, the decoded blocks are the scaled according to the QP parameter. This is equivalent to appending zeros to the bit representation of each sample in the block. This is a lossy operation in the algorithm, as the original bits of the residual transformed block are effectively replaced with zeros.

After scaling, the inverse of the integer transform is performed. The embodiment of the inverse transform is according to the embodiment of the forward transform performed during encoding. This is a lossy operation as the inverse integer transform does not completely and exactly invert the effects of the integer transform during encoding. Performing the entropy decoding in sequence returns the residual blocks b_{i,j} in order of transmission.

In one embodiment, accumulation is provided. In such embodiment, the blocks b_{i,j} are accumulated to get back a_{i,j} as a_{i,1}=b_{i,1} and a_{i,j}=b_{i,j}+b_{i,1} for j=2, 3, . . . , N_{D}/L for j=1,2, . . . , N_{SC}/N.

In one embodiment, (R, G, B)→(I, Q) mapping is provided. In such embodiment, the streams of color data are converted back to I/Q samples by performing the inverse of the mapping used at encoding. All embodiments of this mapping and inverse mapping are one-one and are, hence, lossless.

In one embodiment, the inverse mapping is: (a) I=(2*B(1)−1)*[R B(2:4)] and (b) Q=(2*B(5)−1)*[G B(6:8)].

In one embodiment, the inverse mapping is: (a) I=[R B(1:4)] and (b) Q=[G B(5:8)].

In one embodiment, the inverse mapping is: (a) I=R and (b) Q=G.

FIG. 13 illustrates another examples of decoding process 1300 according to various embodiments of the present disclosure. An embodiment of the decoding process 1300 shown in FIG. 13 is for illustration only.

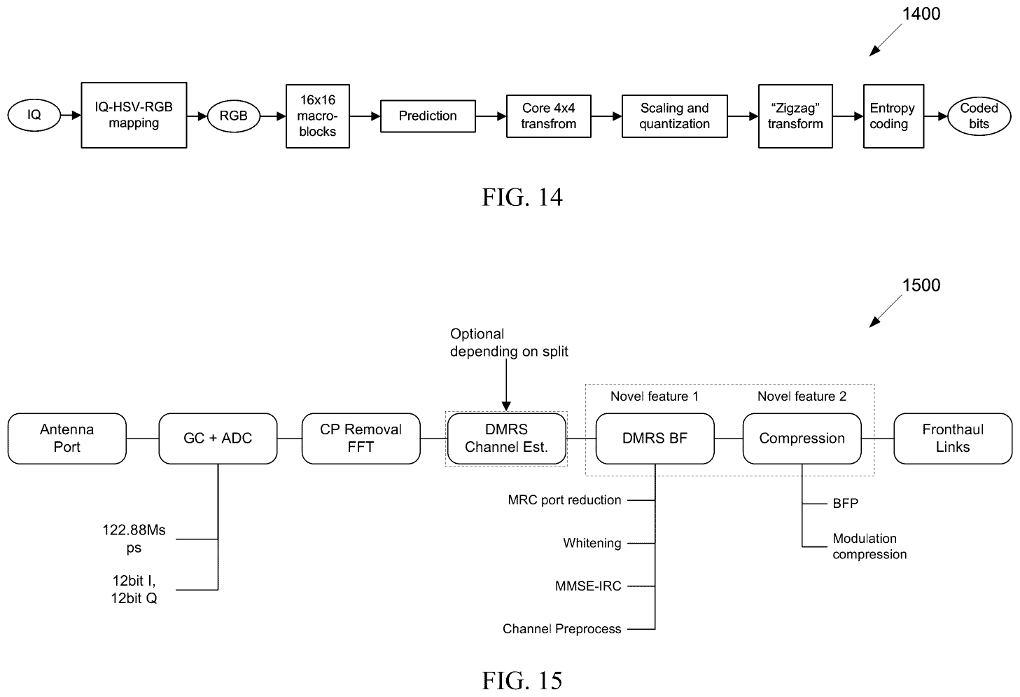

FIG. 14 illustrates an example of sequence of steps in the fronthaul compression at the RU 1400 according to various embodiments of the present disclosure. An embodiment of the sequence of steps in the fronthaul compression at the RU 1400 shown in FIG. 14 is for illustration only.

In one embodiment, (I, Q)→(H, S, V)→(R, G, B) mapping is provided. In such embodiment, the data samples in each stream are represented using 12 bits for I component and 12 bits for Q component. These samples are first converted to HSV domain, and then are converted to an RGB domain.

In one embodiment, the first conversion is carried out as: (1) H=tan⁻¹(Q/I); (2) V=1; and (3) S=√(I²+Q²).

In one embodiment, each of (H, S, V) are represented using 12 bits.

In one embodiment, the second conversion is carried out as:

$$C = V * S ; \qquad ( 1 )$$

$$X = C * ( 1 - \vert 1 - ( H / 60 ° ) mod 2 \vert ) ; \qquad ( 2 )$$

$$M = V - C ; \qquad ( 3 )$$

$$( {R}^{′} , {G}^{′} , {B}^{′} ) = \{ \begin{matrix}( C , X , 0 ) , 0 ° \leq H \leq 60 ° \\ ( X , C , 0 ) , 60 ° \leq H \leq 120 ° \\ ( 0 , C , X ) , 120 ° \leq H \leq 180 ° \\ ( 0 , X , C ) , 180 ° \leq H \leq 240 ° \\ ( X , 0 , C ) , 240 ° \leq H \leq 300 ° \\ ( C , 0 , X ) , 300 ° \leq H \leq 360 °\end{matrix} ; \qquad ( 4 )$$

$$R = {R}^{′} + m ; \qquad ( 5 )$$

$$G = {G}^{′} + m ; and \qquad ( 6 )$$

$$B = {B}^{′} + m . \qquad ( 7 )$$

In one embodiment, a residual computation is provided. In such embodiment, for the residual computation, the same operations as in [T-REC-H.264] is performed.

In one embodiment, transform and scaling are provided. In such embodiment, for the transform and scaling, the same operations as in [T-REC-H.264] is performed.

In one embodiment, an entropy coding is provided. In such embodiment, the same entropy coding as discussed in the mentioned embodiment is carried out.

In one embodiment of DU processing, a decoding is provided. In such embodiment, the decoding follows a similar sequence as described in mentioned embodiment.

In one embodiment, inverse integer transform and scaling are provided. In such embodiment, for the inverse transform and scaling, the same operations as in [T-REC-H.264] is performed.

In one embodiment, a prediction is provided. In such embodiment, for the prediction, the same operations as in [T-REC-H.264] is performed.

In one embodiment, (R, G, B)→(H, S, V)→(I, Q) mapping is provided. In such embodiment, the streams of color data are converted back to I/Q samples by performing the inverse of the mapping used at encoding.

In one embodiment, the RGB to HSV conversion is carried out as:

$${C}_{max} = max ( R , G , B ) ; \qquad ( 1 )$$

$${C}_{min} = min ( R , G , B ) ; \qquad ( 2 )$$

$$Δ = {C}_{max} - {C}_{min} ; \qquad ( 3 )$$

$$V = {C}_{max} ; \qquad ( 4 )$$

$$S = \{ \begin{matrix}0 , {C}_{max} = 0 \\ Δ / {C}_{max} , {C}_{max} \neq 0\end{matrix} ; and \qquad ( 5 )$$

$$H = \{ \begin{matrix}0 ° , Δ = 0 \\ 60 ° * ( \frac{G - B}{Δ} mod 6 ) , {C}_{max} = R \\ 60 ° * ( \frac{B - R}{Δ} + 2 ) , {C}_{max} = G \\ 60 ° * ( \frac{R - G}{Δ} + 4 ) , {C}_{max} = B\end{matrix} . \qquad ( 6 )$$

Then, the HSV to IQ conversion is carried out as: (1) I=S*cos(H) and (2) Q=S*sin(H).

FIG. 15 illustrates an example of RU architecture and algorithms 1500 according to various embodiments of the present disclosure. An embodiment of the RU architecture and algorithms 1500 shown in FIG. 15 is for illustration only. As illustrated in FIG. 15, a block floating point (BFP) compression is performed. Data from every SC is reduced from 12 bit representation to 9 bits mantissa, and a common 4 bit exponent is used per PRB.

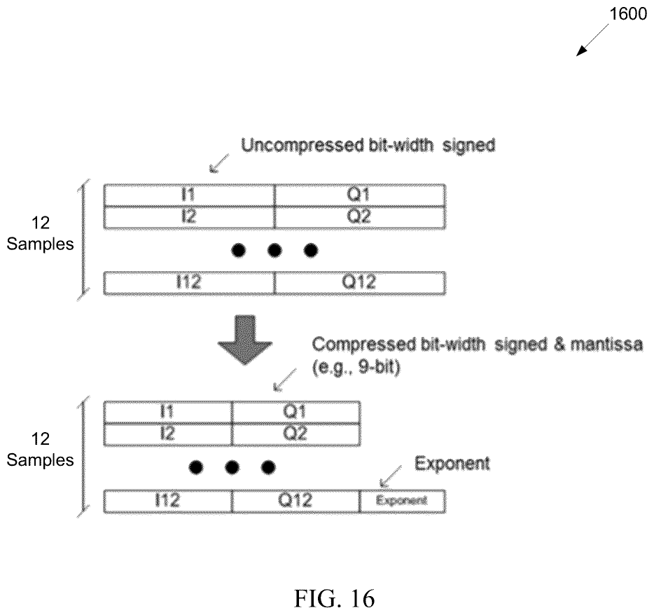

FIG. 16 illustrates an example of compression bit-width 1600 according to various embodiments of the present disclosure. An embodiment of the compression bit-width 1600 shown in FIG. 16 is for illustration only. As illustrated in FIG. 16, 12 samples are used for uncompressed bit-width signed.

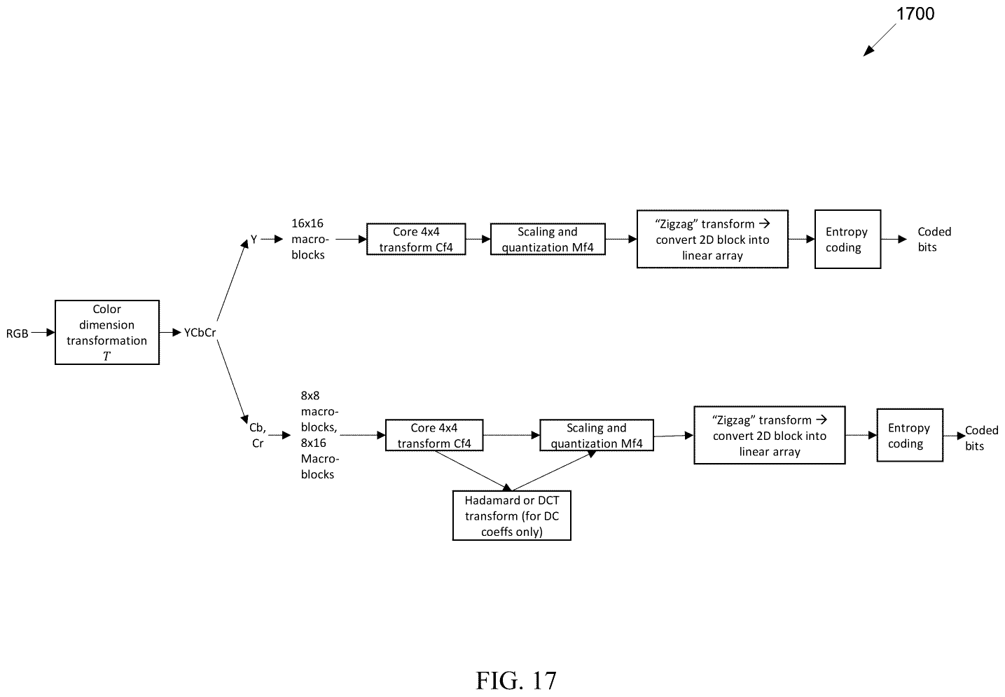

FIG. 17 illustrates an example of H.264 architecture 1700 according to various embodiments of the present disclosure. An embodiment of the H.264 architecture 1700 shown in FIG. 17 is for illustration only. As illustrated in FIG. 17, YCbCr is split into “Y” and “Cr, Cr.” Each branch of the YCbCr is processed with some of function blocks as illustrated in FIG. 17. For the Cb, Cr, the Hadamard or DCT transforms (for DC coeffs only) is applied.

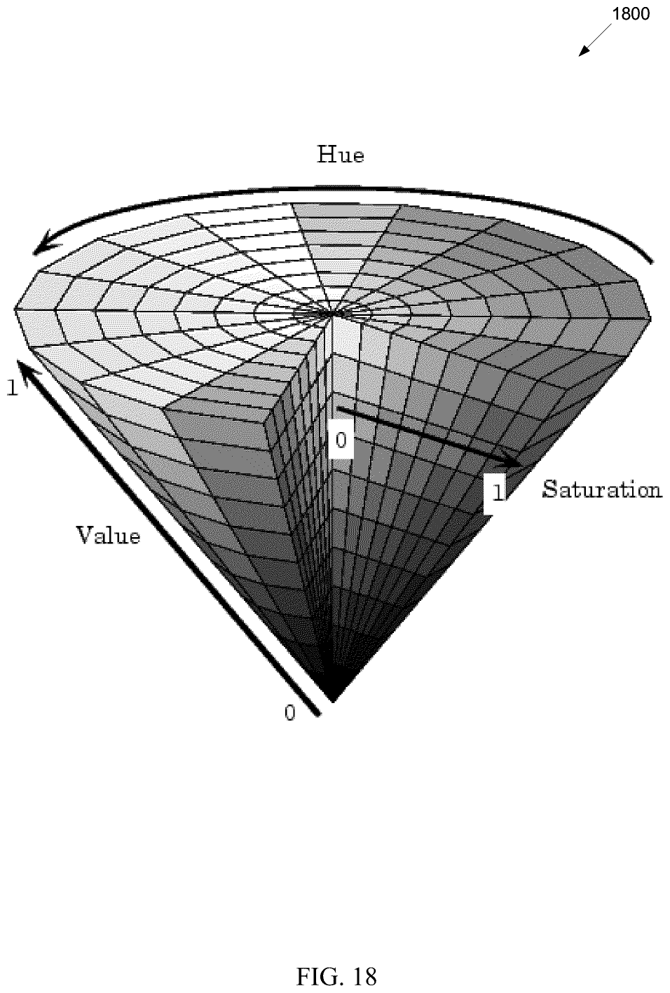

FIG. 18 illustrates an example of color mapping 1800 according to various embodiments of the present disclosure. An embodiment of the color mapping 1800 shown in FIG. 18 is for illustration only. As illustrated in FIG. 18, followings are determined: (1) H=angle(I+jQ); (2) V=1; (3) S=I2+Q2; and (4) Converting from HSV (12 bits) to RGB (8 bits).

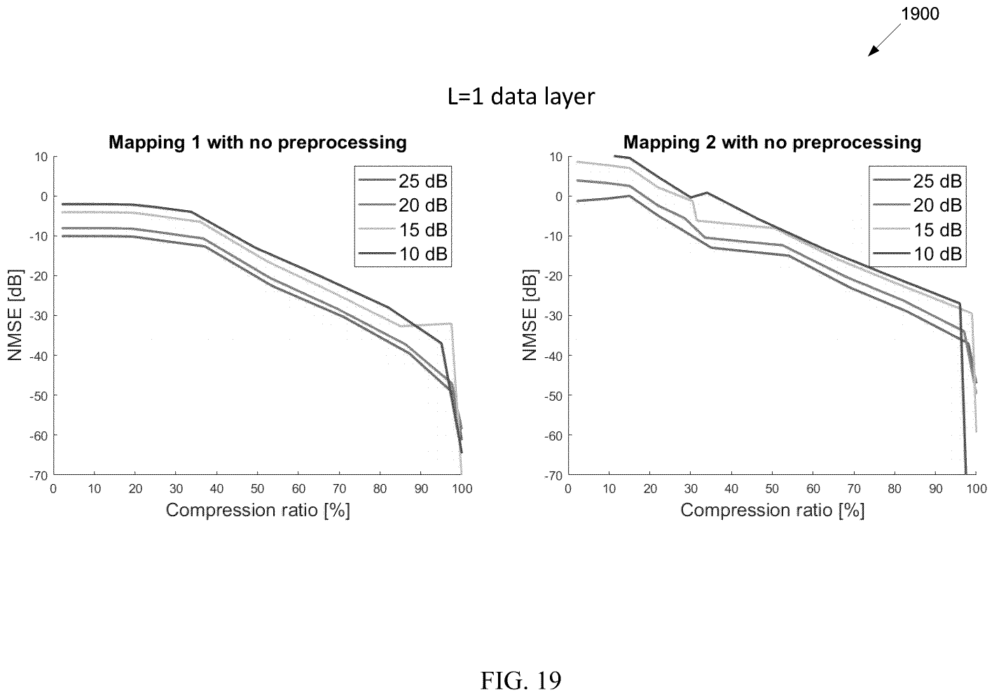

FIG. 19 illustrates an example of NMSE-compression ratio tradeoff with no preprocessing 1900 according to various embodiments of the present disclosure. An embodiment of the NMSE-compression ratio tradeoff with no preprocessing 1900 shown in FIG. 19 is for illustration only.

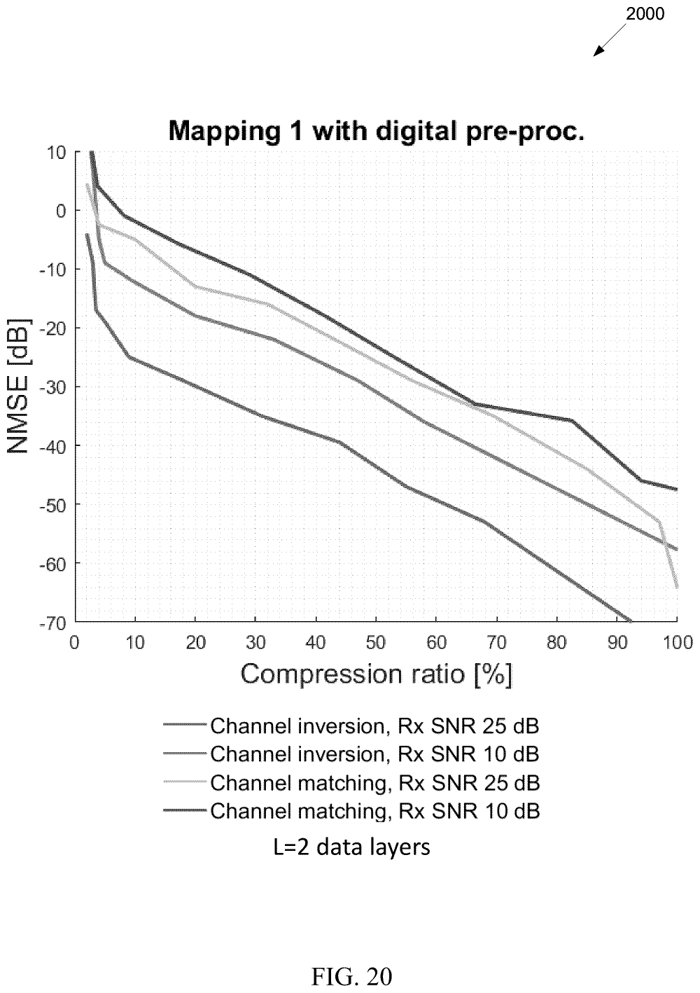

FIG. 20 illustrates an example of NMSE-compression ratio tradeoff with channel inversion and channel matching 2000 according to various embodiments of the present disclosure. An embodiment of the NMSE-compression ratio tradeoff with channel inversion and channel matching 2000 shown in FIG. 20 is for illustration only.

As illustrated in FIG. 19 and FIG. 20, higher Rx SNR generally shows better CR-NMSE tradeoff and mapping 1 generally shows better tradeoff than mapping 2. Further, channel inversion generally performs better than channel matching.

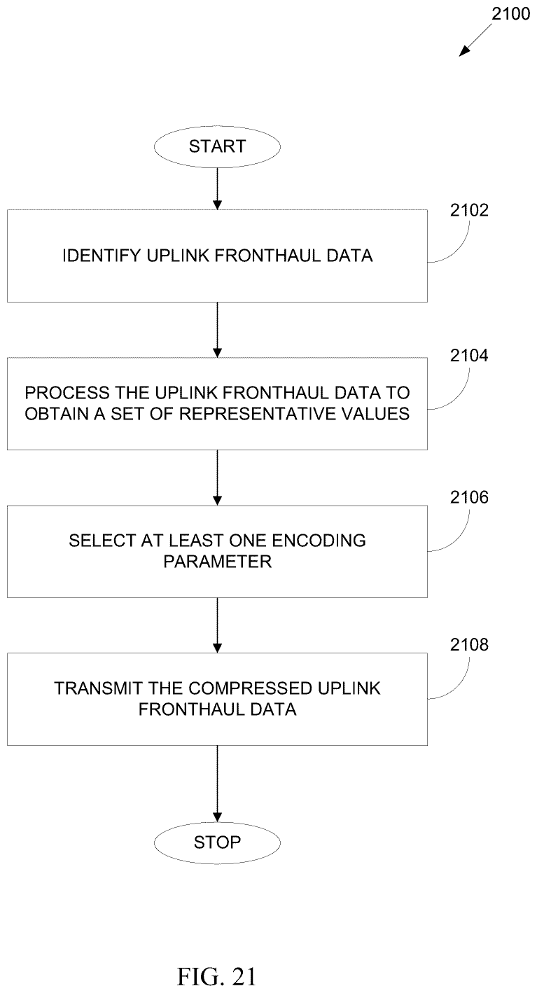

FIG. 21 illustrates a flowchart of RU method 2100 for a bit compression of uplink fronthaul data according to various embodiments of the present disclosure. The RU method 2100 as may be performed by a RU (e.g., UE, 111-116 as illustrated in FIG. 1). An embodiment of the RU method 2100 shown in FIG. 21 is for illustration only. One or more of the components illustrated in FIG. 21 can be implemented in specialized circuitry configured to perform the noted functions or one or more of the components can be implemented by one or more processors executing instructions to perform the noted functions.

In one embodiment, the RU may be implemented as a UE (e.g., 111-116 as illustrated in FIG. 1), a BS (e.g., 101-103 as illustrated in FIG. 1), or an electronic device implemented in the UE or the BS.

In one embodiment, the DU may be implemented as a UE (e.g., 111-116 as illustrated in FIG. 1), a BS (e.g., 101-103 as illustrated in FIG. 1), or an electronic device implemented in the UE or the BS.

As illustrated in FIG. 21, a RU method 2100 begins at step 2102. In step 2102, an RU identifies uplink fronthaul data to reduce a data load on an uplink fronthaul link, wherein the uplink fronthaul link is between the RU and a DU.

In step 2104, the RU processes the uplink fronthaul data to obtain a set of representative values for a compression operation.

In step 2106, the RU selects, based on the set of representative values, at least one encoding parameter for the compression operation.

In step 2108, the RU transmits, to the DU, the uplink fronthaul data that is compressed based on the compression operation.

In one embodiment, the RU performs a digital preprocessing operation using the uplink fronthaul data to induce similarity of the uplink fronthaul data in at least one of a frequency domain, a time domain, and an antenna domain and maps I/Q values included in the uplink fronthaul data to representative RGB values.

In such embodiment, the digital preprocessing operation comprises an invertible operation to reduce information loss and a transparent operation to equalize the uplink fronthaul data including the I/Q values.

In such embodiment, the digital preprocessing operation comprises a channel inversion operation including a channel measurement operation and a first pre-processing operation and a channel matching operation including the channel measurement operation and a second pre-processing.

In one embodiment, a set of representative bits for the RGB values is mapped to: a first sample including (i) 8 bits for an R value in MSBs and (ii) four bits for a B value including a sign bit and three bits in LSBs and a second sample including (i) 8 bits for a G value in the MSBs and (ii) four bits for the B value including a sign bit and three bits in the LSBs; the first sample including (i) 8 bits for the R value in the MSBs and (ii) four bits for the B value in the LSBs and the second sample including (i) 8 bits for the G value in the MSBs and (ii) four bits for the B value in the LSBs; or the first sample including 12 bits for the R value and the second sample including 12 bits for the G.

In one embodiment, the RU selects an entropy coding scheme to compress the uplink fronthaul data into information bits for the compression operation.

In such embodiment, the entropy coding scheme includes at least one of a context-aware variable length coding scheme supporting a 256 of block size, a Huffman coding scheme, and an arithmetic coding scheme.

In one embodiment, the RU performs an LSB truncation operation to increase a ratio of compression for the compression operation.

In one embodiment, the RU selects a difference coding scheme to compute residuals of the uplink fronthaul data for the compression operation.

The above flowcharts illustrate example methods that can be implemented in accordance with the principles of the present disclosure and various changes could be made to the methods illustrated in the flowcharts herein. For example, while shown as a series of steps, various steps in each figure could overlap, occur in parallel, occur in a different order, or occur multiple times. In another example, steps may be omitted or replaced by other steps.

Although the present disclosure has been described with exemplary embodiments, various changes and modifications may be suggested to one skilled in the art. It is intended that the present disclosure encompass such changes and modifications as fall within the scope of the appended claims. None of the description in this application should be read as implying that any particular element, step, or function is an essential element that must be included in the claims scope. The scope of patented subject matter is defined by the claims.

What is claimed is:

1. A radio unit (RU) in a wireless communication system, the RU comprising:
a processor configured to:
identify uplink fronthaul data to reduce a data load on an uplink fronthaul link, wherein the uplink fronthaul link is between the RU and a distributed unit (DU),
process the uplink fronthaul data to obtain a set of representative values for a compression operation, and
select, based on the set of representative values, at least one encoding parameter for the compression operation; and
a transceiver operably coupled to the processor, the transceiver configured to transmit, to the DU, the uplink fronthaul data that is compressed based on the compression operation.

2. The RU of claim 1, wherein the processor is further configured to:
perform a digital preprocessing operation using the uplink fronthaul data to induce similarity of the uplink fronthaul data in at least one of a frequency domain, a time domain, and an antenna domain; and
map in-phase and quadrature (I/Q) values included in the uplink fronthaul data to representative red-green-blue (RGB) values.

3. The RU of claim 2, wherein the digital preprocessing operation comprises:
a channel inversion operation including a channel measurement operation and a first pre-processing operation; and
a channel matching operation including the channel measurement operation and a second pre-processing.

4. The RU of claim 2, wherein a set of representative bits for the RGB values is mapped to:
a first sample including (i) 8 bits for a red (R) value in most significant bits (MSBs) and (ii) four bits for a blue (B) value including a sign bit and three bits in least significant bit (LSBs) and a second sample including (i) 8 bits for a green (G) value in the MSBs and (ii) four bits for the B value including a sign bit and three bits in the LSBs;
the first sample including (i) 8 bits for the R value in the MSBs and (ii) four bits for the B value in the LSBs and the second sample including (i) 8 bits for the G value in the MSBs and (ii) four bits for the B value in the LSBs; or
the first sample including 12 bits for the R value and the second sample including 12 bits for the G value.

5. The RU of claim 2, wherein the digital preprocessing operation comprises an invertible operation to reduce information loss and a transparent operation to equalize the uplink fronthaul data including the I/Q values.

6. The RU of claim 1, wherein the processor is further configured to select an entropy coding scheme to compress the uplink fronthaul data into information bits for the compression operation.

7. The RU of claim 6, wherein the entropy coding scheme includes at least one of a context-aware variable length coding scheme supporting a 256 of block size, a Huffman coding scheme, and an arithmetic coding scheme.

8. The RU of claim 1, wherein the processor is further configured to perform a least significant bit (LSB) truncation operation to increase a ratio of compression for the compression operation.

9. The RU of claim 1, wherein the processor further configured to select a difference coding scheme to compute residuals of the uplink fronthanl data for the compression operation.

10. A method of a radio unit (RU) in a wireless communication system, the method comprising:)
identifying uplink fronthaul data to reduce a data load on an uplink fronthaul link, wherein the uplink fronthaul link is between the RU and a distributed unit (DU);
processing the uplink fronthaul data to obtain a set of representative values for a compression operation;
selecting, based on the set of representative values, at least one encoding parameter for the compression operation; and
transmitting, to the DU, the uplink fronthaul data that is compressed based on the compression operation.

11. The method of claim 10, further comprising:
performing a digital preprocessing operation using the uplink fronthaul data to induce similarity of the uplink fronthaul data in at least one of a frequency domain, a time domain, and an antenna domain; and
mapping in-phase and quadrature (I/Q) values included in the uplink fronthaul data to representative red-green-blue (RGB) values.

12. The method of claim 11, wherein the digital preprocessing operation comprises:
a channel inversion operation including a channel measurement operation and a first pre-processing operation; and
a channel matching operation including the channel measurement operation and a second pre-processing.

13. The method of claim 11, wherein a set of representative bits for the RGB values is mapped to:
a first sample including (i) 8 bits for a red (R) value in most significant bits (MSBs) and (ii) four bits for a blue (B) value including a sign bit and three bits in least significant bit (LSBs) and a second sample including (i) 8 bits for a green (G) value in the MSBs and (ii) four bits for the B value including a sign bit and three bits in the LSBs;
the first sample including (i) 8 bits for the R value in the MSBs and (ii) four bits for the B value in the LSBs and the second sample including (i) 8 bits for the G value in the MSBs and (ii) four bits for the B value in the LSBs; or
the first sample including 12 bits for the R value and the second sample including 12 bits for the G value.

14. The method of claim 11, wherein the digital preprocessing operation comprises an invertible operation to reduce information loss and a transparent operation to equalize the uplink fronthaul data including the I/Q values.

15. The method of claim 10, further comprising selecting an entropy coding scheme to compress the uplink fronthaul data into information bits for the compression operation.

16. The method of claim 15, wherein the entropy coding scheme includes at least one of a context-aware variable length coding scheme supporting a 256 of block size, a Huffman coding scheme, and an arithmetic coding scheme.

17. The method of claim 10, further comprising performing a least significant bit (LSB) truncation operation to increase a ratio of compression for the compression operation.

18. The method of claim 10, further comprising selecting a difference coding scheme to compute residuals of the uplink fronthanl data for the compression operation.

19. A non-transitory computer-readable medium comprising program code, that when executed by at least one processor of an electronic device, causes the electronic device to:
identify uplink fronthaul data to reduce a data load on an uplink fronthaul link, wherein the uplink fronthaul link is between a radio unit (RU) and a distributed unit (DU);
process the uplink fronthaul data to obtain a set of representative values for a compression operation;
select, based on the set of representative values, at least one encoding parameter for the compression operation; and
transmit, to the DU, the uplink fronthaul data that is compressed based on the compression operation.

20. The non-transitory computer-readable medium of claim 19, further comprising program code, that when executed by the at least one processor, causes the electronic device to store
performing a digital preprocessing operation using the uplink fronthaul data to induce similarity of the uplink fronthaul data in at least one of a frequency domain, a time domain, and an antenna domain; and
mapping in-phase and quadrature (I/Q) values included in the uplink fronthaul data to representative red-green-blue (RGB) values.
